(19) United States
(12) Patent Application Publication
(10) Pub. No.: US 2012/0244696 A1
(43) Pub. Date: Sep. 27, 2012

(54) METHOD OF MANUFACTURING SEMICONDUCTOR DEVICE

(75) Inventor: Hidenobu NAGASHIMA, Yokkaichi (JP)

(73) Assignee: KABUSHIKI KAISHA TOSHIBA, Tokyo (JP)

(21) Appl. No.: 13/428,046

(22) Filed: Mar. 23, 2012

(30) Foreign Application Priority Data
Mar. 23, 2011 (JP) 2011-064341

(51) Int. Cl. H01L 21/3213

(52) U.S. Cl. 438/593; 257/E21.209

(57) ABSTRACT

A method of manufacturing a semiconductor device is disclosed. The method includes forming a third film so as to cover a second pattern, a second mask pattern, and a first film; etching back the third film to form a first sidewall line pattern along a sidewall of the second pattern and to form a first sidewall mask pattern along a sidewall of the second mask pattern; forming a third mask pattern comprising a resist film so as to cover the second mask pattern and the first sidewall mask pattern; and selectively removing the second pattern using the third mask pattern as a mask and thereafter removing the third mask pattern.

### CROSS-REFERENCE TO RELATED APPLICATION(S)

This application is based upon and claims the benefit of priority from Japanese Patent Application No. 2011-064341, filed on, Mar. 23, 2011 the entire contents of which are incorporated herein by reference.

### FIELD

Embodiments disclosed herein generally relate to a method of manufacturing a semiconductor device.

### BACKGROUND

Driven by demands to increase the storage capacity with reduced cost, device elements of NAND flash memories, typically interconnects such as bit lines and word lines are formed and densely packed in tighter pitches. With advances in microfabrication, methodologies for forming micro patterns beyond the resolution limits of exposure apparatuses are increasing their significance in device manufacturing. Sidewall transfer process is one of such methodologies and allows formation of features that reduces the pitch of lithographic exposure patterns by ½. By repeating the iteration of the sidewall transfer process, the pitch of lithographic exposure patterns can be reduced to ¼.

Sidewall transfer process typically includes: formation of a core pattern by etching a sacrificial film using an exposure pattern as a mask; forming a sidewall pattern along the sidewall of the core pattern; etching the underlying structure using the sidewall pattern as a mask to obtain a feature which is ½ the pitch of the exposure pattern. By repeating the above described steps, that is, by further forming a sidewall pattern along the sidewall of the halved pattern and using the sidewall pattern to etch the underlying structure, the exposure pattern can be further reduced to ¼ of the original pitch.

However, formation of ¼ pitched patterns will confine the number of patterns that can be formed, that is, in the case of a NAND flash memory, the number of memory cells that can be formed, to a multiple of 4. In other words, n number of memory cells which is a multiple of 2 but not a multiple of 4 cannot be formed. Such limitation will result in unnecessary increase in the number of memory cells and will lead to an increase in the length of the NAND string and consequently an increase in the chip size.

### BRIEF DESCRIPTION OF THE DRAWINGS

FIG. 1 is a partial equivalent circuit representation of an electrical configuration of a NAND flash memory of the first embodiment.

FIG. 2 schematically illustrates the planar structure of a memory cell region of a first embodiment.

FIG. 3A is a schematic cross sectional view taken along line 3A-3A of FIG. 2.

FIG. 3B is a schematic cross sectional view taken along line 3B-3B of FIG. 2.

FIGS. 4A, 5A, 6A, 7A, 8A, 9A, 10A, 11A, 12A, 13A, 14A, 15A, 16A, 17A, 18A, and 19A, each depicts a cross section taken along the extension of line 3A-3A of FIG.2 and illustrate one phase of a manufacturing process flow of the memory cell region.

FIGS. 4B, 5B, 6B, 7B, 8B, 9B, 10B, 11B, 12B, 13B, 14B, 15B, 16B, 17B, 18B, and 19B, each provides a top view of the manufacturing phases illustrated in the cross sectional views of FIGS. 4A, 5A, 6A, 7A, 8A, 9A, 10A, 11A, 12A, 13A, 14A, 15A, 16A, 17A, 18A, and 19A.

FIG.20 illustrates a second embodiment and corresponds to FIG. 5.

FIGS. 21, 22, 23, 24, 25, 26, 27, 28, 29, 30, and 31 correspond to FIGS. 6, 7, 8, 9, 10, 11, 12, 13, 14, 15, and 16, respectively.

FIG. 32 illustrates a third embodiment and corresponds to FIG. 21.

FIGS. 33, 34, 35, 36, 37, 38, 39, 40, 41 correspond to FIGS. 22, 23, 24, 26, 27, 28, 29, 30, and 31, respectively.

### DETAILED DESCRIPTION

In one embodiment, a method of manufacturing a semiconductor device is disclosed. The method includes forming a first film and a second film in the listed sequence above a base structure; forming a resist film above the second film; patterning the resist film to form a first pattern in each of a plurality of first regions and to form a first mask pattern in a second region interposing adjacent first regions; slimming a width of the first pattern and a width of the first mask pattern; etching the second film using the first pattern and the first mask pattern as masks to form a second pattern and a second mask pattern; forming a third film so as to cover the second pattern, the second mask pattern, and the first film; etching back the third film to expose upper surfaces of the second pattern and the second mask pattern to form a first sidewall line pattern along a sidewall of the second pattern and to forma first sidewall mask pattern along a sidewall of the second mask pattern; forming a third mask pattern comprising a resist film so as to cover the second mask pattern and the first sidewall mask pattern; selectively removing the second pattern using the third mask pattern as a mask and thereafter removing the third mask pattern; etching the first film using the first sidewall line pattern, the first sidewall mask pattern, and the second mask pattern as masks to form a second sidewall line pattern and a fourth mask pattern; forming a fourth film so as to cover the second sidewall line pattern, the fourth mask pattern, and the base structure; etching back the fourth film to expose upper surfaces of second sidewall line pattern and the fourth mask pattern to forma third sidewall line pattern along a sidewall of the second sidewall line pattern and to form a second sidewall mask pattern along a sidewall of the fourth mask pattern; selectively removing the second sidewall line pattern and the fourth mask pattern; and patterning the base structure using the third sidewall line pattern and the second sidewall mask pattern as masks.

Embodiments are described hereinafter with reference to the accompanying drawings. Elements that are identical or similar are represented by identical or similar reference symbols across the figures. The drawings are not drawn to scale and thus, do not reflect the actual measurements of the features such as the correlation of thickness to planar dimensions and the relative thickness of different layers.

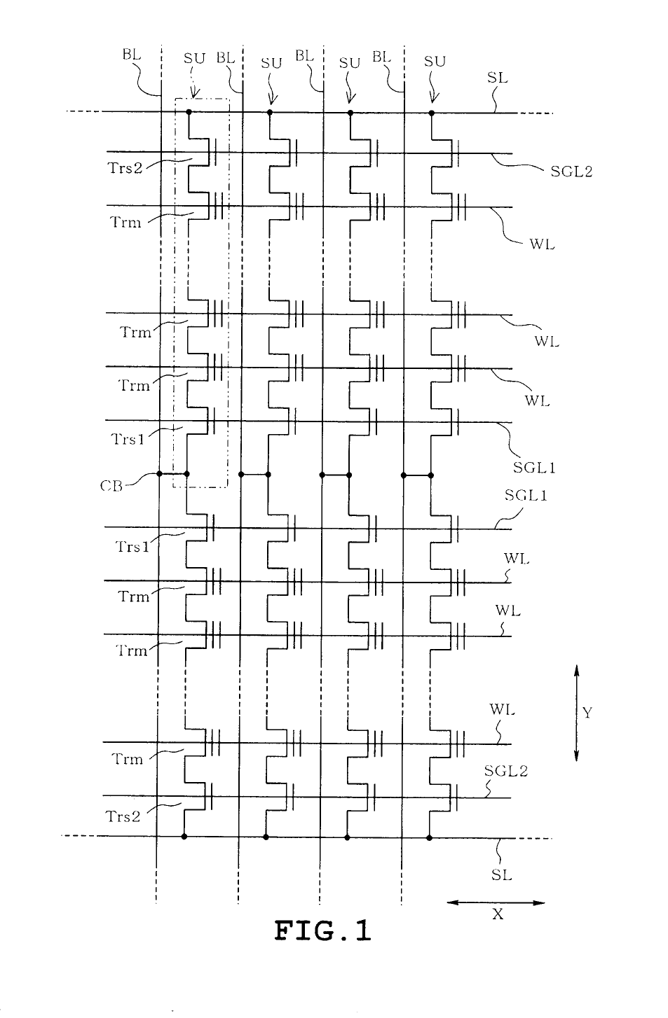

FIG. 1 is a partial equivalent circuit representation of a memory cell array formed in a memory cell region of NAND flash memory 1. The memory cell array is a collection of units of NAND cells also referred to as NAND cell unit SU arranged in rows and columns. NAND cell unit SU comprises a multiplicity of series connected memory cell transistors Trm, such as 34 in number, situated between a couple of select transistors Trs1 and Trs2 that are located at the ends of NAND cell unit SU. The neighboring memory cell transistors Trm within NAND cell unit SU share their source/drain regions.

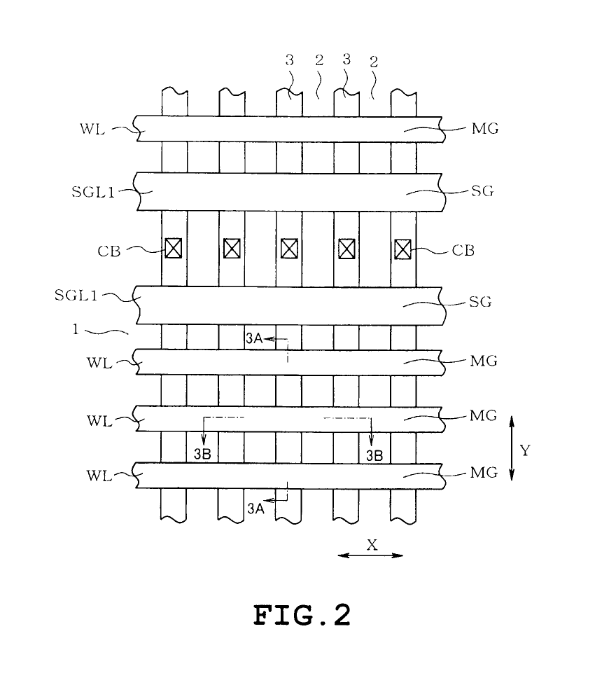

The X-direction aligned memory cell transistors Trm shown in FIG. 1 are interconnected by common word line WL, whereas the X-direction aligned select transistors Trs1 are electrically interconnected by common select gate line SGL1 and likewise, the X-direction aligned select transistors Trs2 are electrically interconnected by common select gate line SGL2. The drain of each select transistor Trs1 is coupled to bit line BL by way of bit line contact CB in FIG. 2. Bit line BL extends in the Y direction orthogonal to the X direction shown in FIG. 1. The source of select transistor Trs2 is coupled to source line SL extending in the X-direction as shown in FIG. 1. As apparent from FIG. 1, the X direction indicates the direction in which word line WL extends or the width direction of the gate structures later described, whereas the Y direction indicates the direction in which bit line BL extends or the length direction of the gate structures.

FIG.2 provides planar layout of the memory cell region in part. As shown, multiplicity of isolation regions 2 formed by STI (Shallow Trench Isolation) scheme run in the Y direction as viewed in FIG. 2 of silicon substrate 1, or more generally, semiconductor substrate 1. Isolation regions 2 are separated from one another in the X direction as viewed in FIG. 2 to isolate active areas 3, running in the Y-direction. Multiplicity of word lines WL, spaced from one another in the Y direction by a predetermined spacing, extend in the X direction as viewed in FIG. 2 which is the direction orthogonal to the Y direction in which active area 3 extends.

As shown in FIG. 2, a pair of X directional select gate lines SGL1 each connected to select transistor Trs1 oppose each other in the Y direction. Between the Y directionally opposing select gate lines SGL1, bit line contacts CB are formed. Above active area 3 intersecting with word line WL, memory cell gate electrode MG of memory cell transistor Trm is formed. Above active area 3 intersecting with select gate line SGL1, select gate electrode SG of select transistor Trs1 is formed.

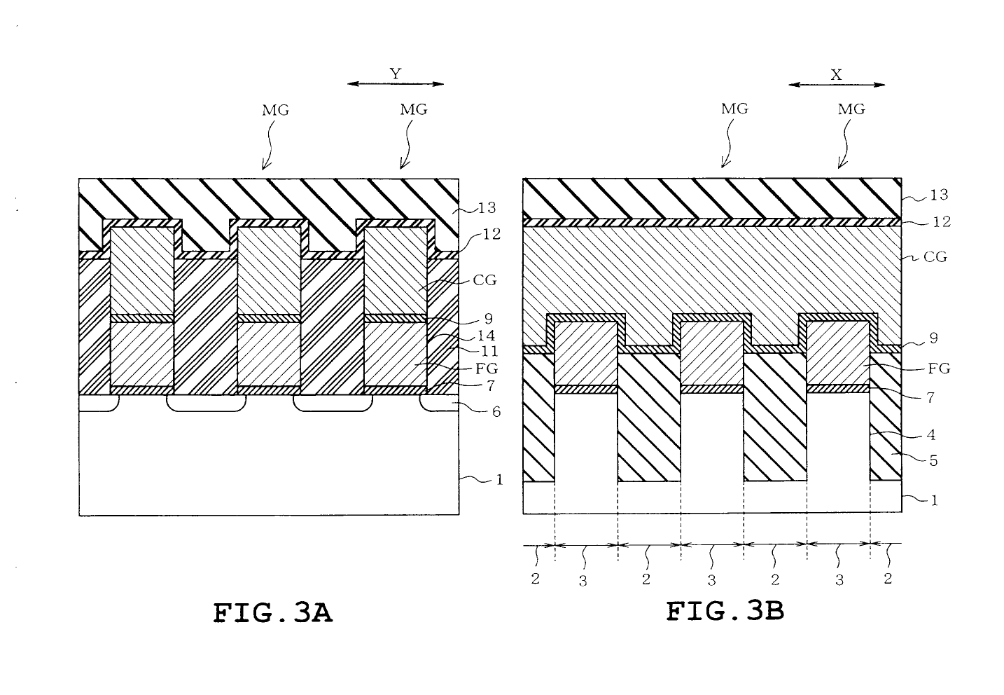

Next, a description is given on the gate electrode structures of the within the memory cell region of the first embodiment with reference to FIGS. 3A and 3B. FIG. 3A is a schematic cross sectional view taken along line 3A-3A of FIG. 1 which extends along bit line BL or the Y direction. FIG. 3B is a schematic cross sectional view taken along line 3B-3B of FIG. 1 which extends along word line WL or the X direction.

As can be seen in FIGS. 3A and 3B, the P-type silicon substrate 1 has element isolation trenches 4 formed in its surface layer. Element isolation trenches 4 isolate multiplicity of active regions 3 in the X direction as viewed in FIG. 1. Each element isolation trench 4 is filled with element isolation insulating film 5 to form element isolation region 2 employing an STI (Shallow Trench Isolation) scheme.

Memory cell transistor Trm includes an n-type diffusion layer 6 formed in silicon substrate 1, gate insulating film 7 formed on silicon substrate 1, and gate electrode MG formed above gate insulating film 7. Gate electrode MG includes floating gate electrode FG serving as a charge storage layer, interelectrode insulating film 9 formed above floating gate electrode FG, and control gate electrode CG formed above interelectrode insulating film 9. Diffusion layer 6 is formed in the surface layer of silicon substrate 1 situated beside gate electrode MG of memory cell transistor Trm and serves as the source/drain region of memory cell transistor Trm.

Gate insulating film 7 is formed in active region 3 of silicon substrate 1. Gate insulating film 7 typically comprises a silicon oxynitride film. Floating gate electrode FG formed above gate insulating film 7, serving as a charge storage layer as described earlier, typically comprises polycrystalline silicon layer 8 also referred to as conductive layer 8 doped with impurities such as phosphorous.

Interelectrode insulating film 9 takes a multilayered ONO structure in which a layer of silicon oxide film, a layer of silicon nitride film, and a layer of silicon oxide film are stacked in the listed sequence above the upper surface of element isolation insulating film 5 and the upper sidewall and the upper surface of floating gate electrode FG. Interelectrode insulating film 9 may also be referred to as an interpoly insulating film and inter-conductive-layer insulating film. Each layer of the ONO structure in the first embodiment is 3 to 10 nm thick.

Control gate electrode CG formed above interelectrode insulating film 9 comprises conductive layer 10. In other words, conductive layer 10 serves globally as word line WL extending across the memory cell array and locally as control gate electrode CG for each memory cell. Conductive layer 10 is typically configured as a stack of a polycrystalline silicon layer doped with impurities such as phosphorous and a silicide layer residing directly on top of the polycrystalline silicon layer. The silicide layer comprises a silicide of either of metals such as tungsten (W), cobalt (Co), and nickel (Ni). The silicide layer of the first embodiment employs a nickel silicide (NiSi),In an alternative embodiment, conductive layer 10 may be fully silicided.

As can be seen in FIG. 3A, gate electrodes MG of memory cell transistors Trm are electrically isolated in the Y direction by gaps. The gaps are filled with inter-memory-cell insulating film 11 which typically comprises a silicon oxide film such as TEOS (tetraethyl orthosilicate) or a low dielectric constant insulating film.

Above the upper surface of inter-memory-cell insulating film 11, and the upper surface and the upper sidewall of control gate electrode CG, liner insulating film 12 is formed which comprises, for example, a silicon nitride film. Further above liner insulating film 12, interlayer insulating film 13 is formed which comprises a silicon oxide film. Liner insulating film 12 serves as a barrier to keep the oxidants used in the formation of interlayer insulating film 13 away from control gate electrode CG. One of the advantages of providing liner insulating film 12 is that it prevents oxidation of the silicide layer of conductive layer 10 which may cause elevation in the resistance level of word line WL. Because liner insulating film 12, comprising a silicon nitride film in the first embodiment, does not fully fill the gap between control gate electrode CG, the risk of increased parasitic capacitance that may lead to wiring delay can be minimized.

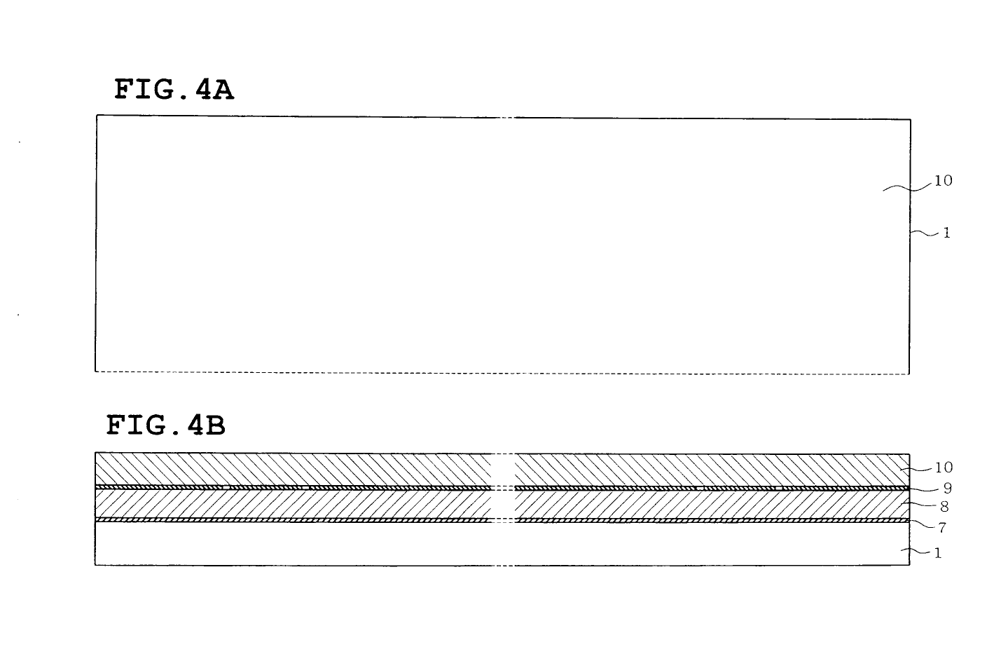

Next, a description will be given on a process flow employed in manufacturing the NAND flash memory structured as described above with reference to FIGS. 4A to 19A as well as FIGS. 4B to 19B. The first embodiment employs the process flow to the isolation of gate electrodes MG serving as word lines WL.

FIGS. 4A to 19A are schematic cross sectional views corresponding to FIG. 3A and each depicts one phase of the process flow for obtaining a structure including word lines WL interposed between a pair of select gate lines SGL 1 and SGL 2. FIGS. 4B to 19B each provides a top view of the corresponding phases of the process flow depicted in FIGS. 4A to 19A.

FIGS. 4A and 4B depict a structure including silicon substrate 1, gate insulating film 7 formed on silicon substrate 1, a stack including polycrystalline silicon layer 8, interelectrode insulating film 9, and polycrystalline layer 10 laminated in the listed sequence above gate insulating film 7. The stack formed above gate insulating film 7 serves as the workpiece, in other words, the base structure for forming gate electrodes MG. In the portion of interelectrode insulating film 9 designed for forming select gate lines SGL1 and SGL2, in other words, select gate electrodes SG, a vertical through hole is formed to interconnect polycrystalline silicon layer 8 and the overlying polycrystalline silicon layer 10.

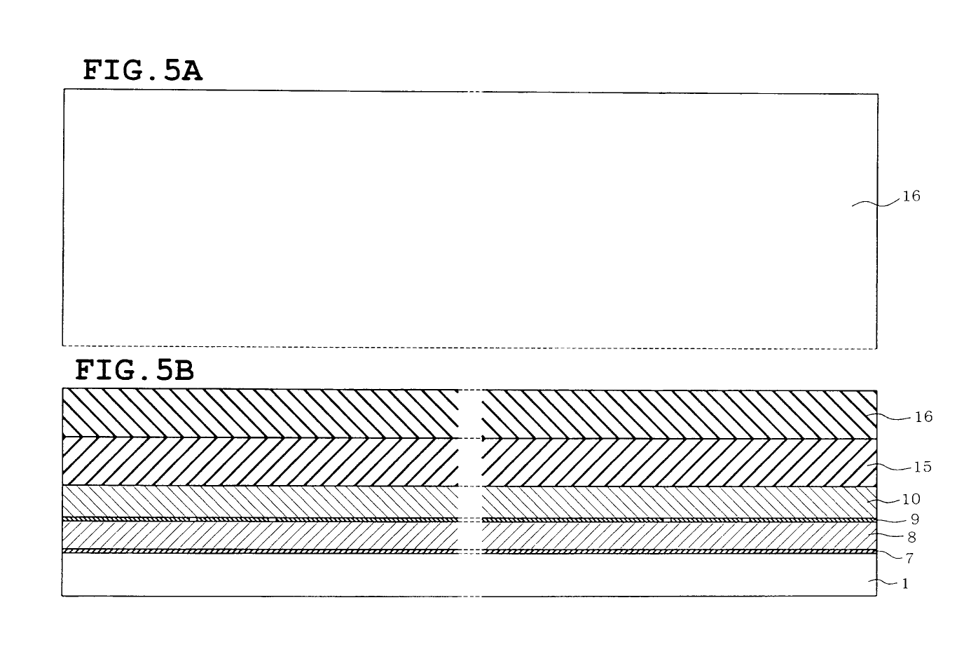

Then, as shown in FIGS. 5A and 5B, silicon nitride film 15 serving as a mask also referred to as a first film is formed above polycrystalline silicon layer 10, whereafter silicon oxide film 16 serving as a mask also referred to as a second film is formed above silicon nitride film 15.

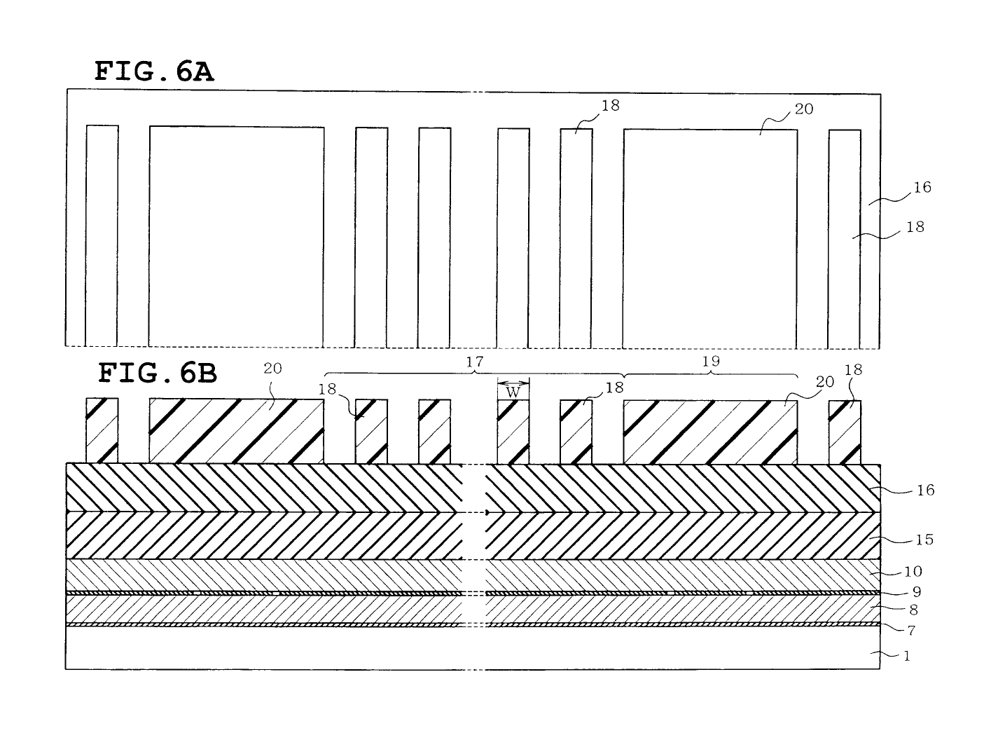

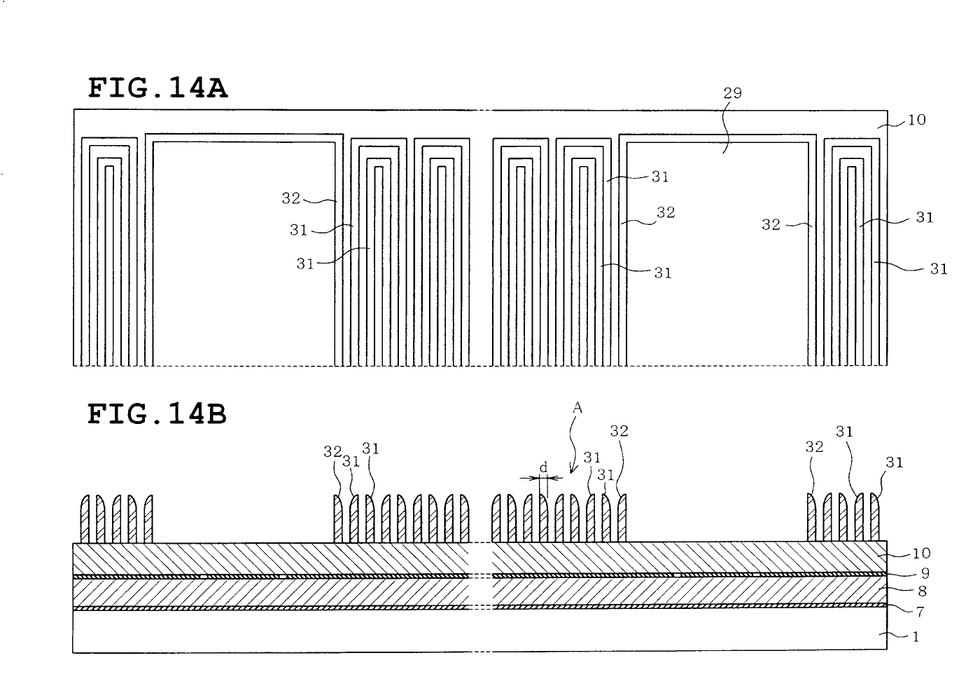

Referring to FIGS. 6A and 6B, photoresist pattern 18 also referred to as a first pattern is formed above silicon oxide film 16 by ordinary photolithography to form multiple line and space patterns in each of word line forming regions 17 also referred to as a first region. The line patterns of photoresist pattern 18 are spaced from one another in the bit line direction which is oriented in the left and right direction as viewed in FIG. 6A and the line and space patterns are formed at first pitch P1. When photoresist pattern 18 is formed, photoresist pattern 20 also referred to as first mask pattern is formed above silicon oxide film 16 by ordinary photolithograpy so as to extend along the entire length of each of select gate line forming regions 19 also referred to as second region. In the first embodiment, the number of line patterns within photoresist pattern 18 formed in word line forming region 17 is specified to “8”. This is based on the assumption that “34” lines are to be formed in the final structure represented as shrink pattern A in FIG. 14A. Based on such assumption, the number of line patterns to be formed within photoresist pattern 18, which is “8” in this case, is obtained by subtracting “2” from “34” and dividing the difference “32” with “4”. Based on such configuration, width d of the line pattern or the space pattern of the final shrink pattern A is ¼ of width W of the line or the space pattern photoresist pattern 18. The spacing between photoresist pattern 18 and photoresist pattern 20 is configured at a width equivalent to width W of the lines or the spaces of photoresist pattern 18. The width is taken in the direction of W indicated in FIG. 6A.

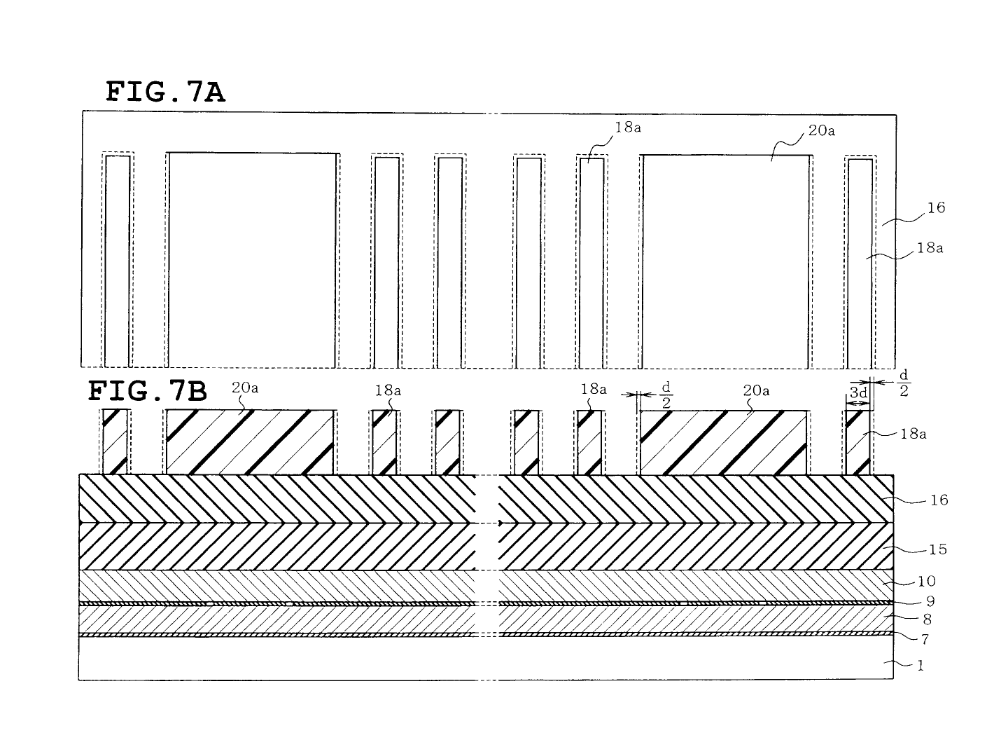

Then, as shown in FIGS. 7A and 7B, an ordinary slimming technique is used to slim or thin photoresist pattern 18. The lines of photoresist pattern 18 is slimmed on both sides by width d/2 to obtain photoresist pattern 18a which has lines measuring width 3d and spaces measuring width 5d. Photoresist pattern 20, on the other hand, is slimmed on both sides to obtain photoresist pattern 20a.

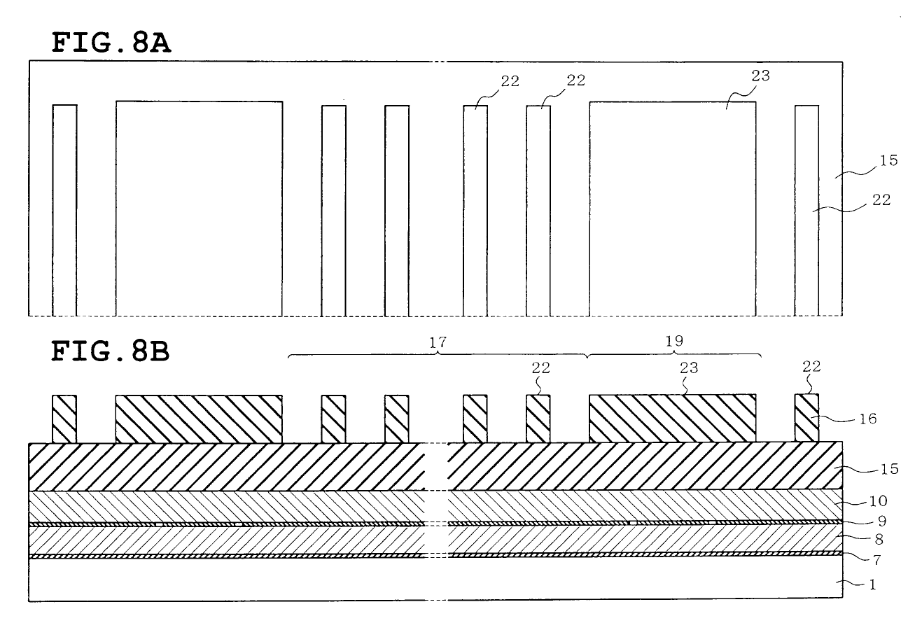

Then, as shown in FIGS. 8A and 8B, photoresist patterns 18a and 20a are used as masks to pattern silicon oxide film 16 by RIE (reactive ion etching). As a result, dummy line pattern 22 also referred to as second pattern is formed in word line forming region 17. In select gate line forming region 19, on the other hand, dummy mask pattern 23 also referred to as second mask pattern is formed.

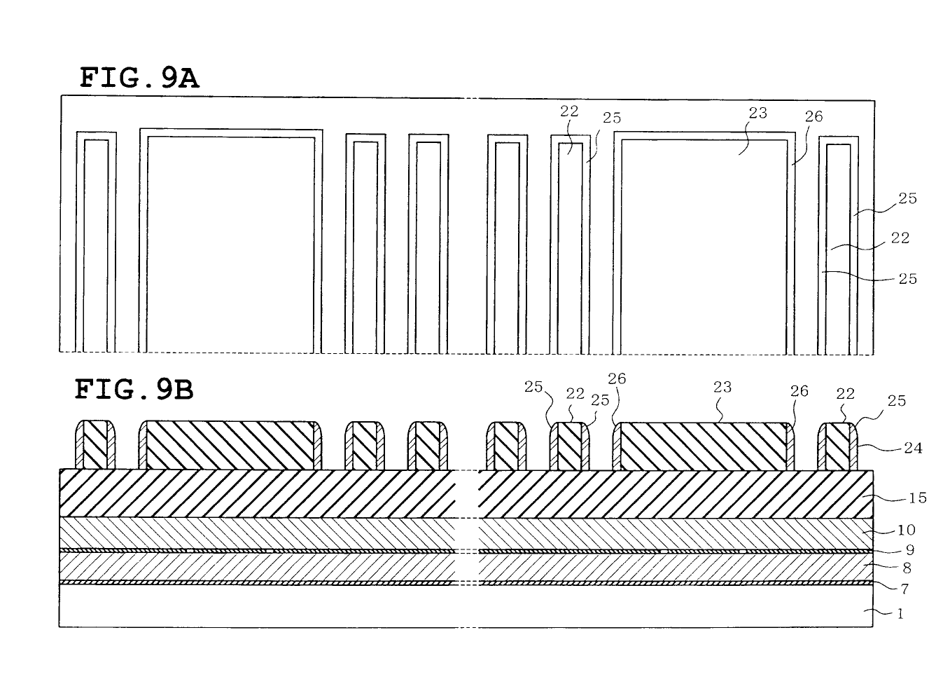

Then, amorphous silicon film 24 also referred to as a third film is blanket deposited by CVD (chemical vapor deposition) in the thickness substantially equal to width d to cover dummy line pattern 22 and dummy mask pattern 23 by amorphous silicon film 24. Then, amorphous silicon film 24 is etched back by anisotropic etching such as RIE to expose the upper surfaces of dummy line pattern 22 and dummy mask pattern 23 as shown in FIGS. 9A and 9B. This leaves sidewall line pattern 25 also referred to as a first sidewall line pattern along the sidewall or the side surface of dummy line pattern 22 as well as sidewall mask pattern 26 also referred to as a first sidewall mask pattern along the sidewall or the side surface of dummy mask pattern 23. The widths of sidewall line pattern 25 and sidewall mask pattern 26 are controlled to width d.

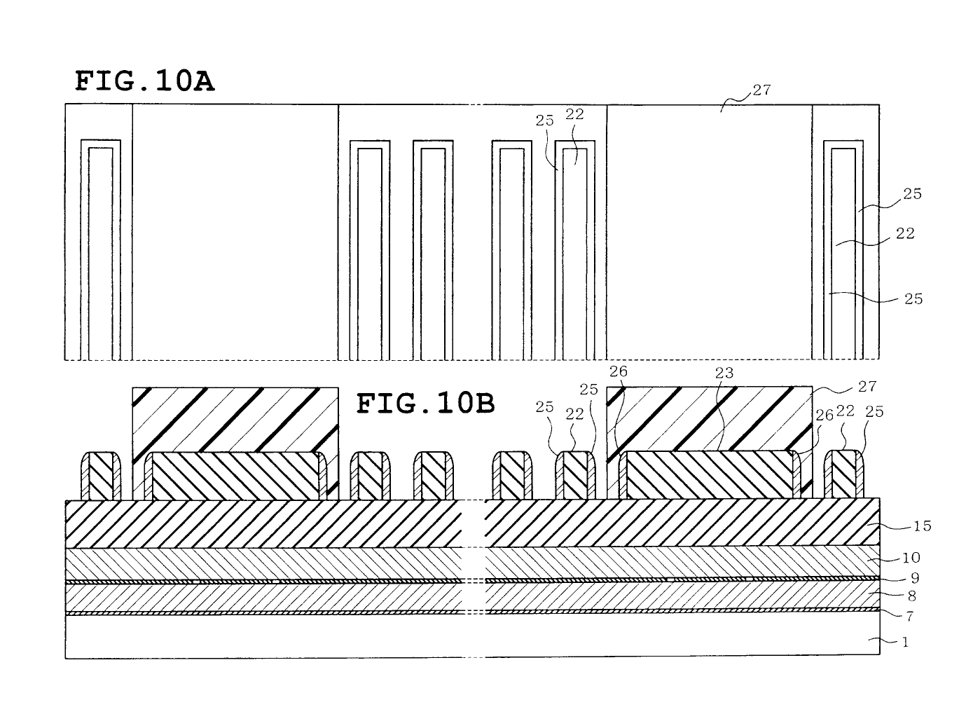

Then, as shown in FIGS. 10A and 10B, sidewall mask pattern 26 and dummy mask pattern 23 in select gate line forming region 19 are covered by photoresist pattern 27 also referred to as third mask pattern.

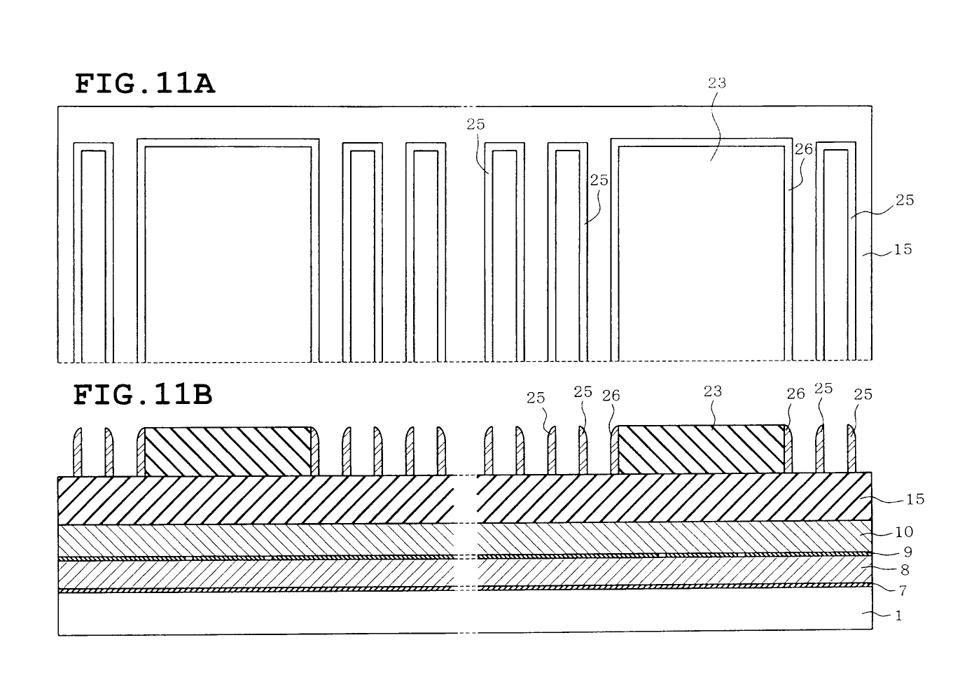

Then, as shown in FIGS. 11A and 11B, dummy line pattern 22 is removed by wet etching using wet etchant such as hydrofluoric acid. At this instance, dummy mask pattern 23 is covered by photoresist pattern 27 and thus, stays unremoved and is later used as a mask. FIGS. 11A and 11B show the structure with photoresist pattern 27 removed after the wet etching.

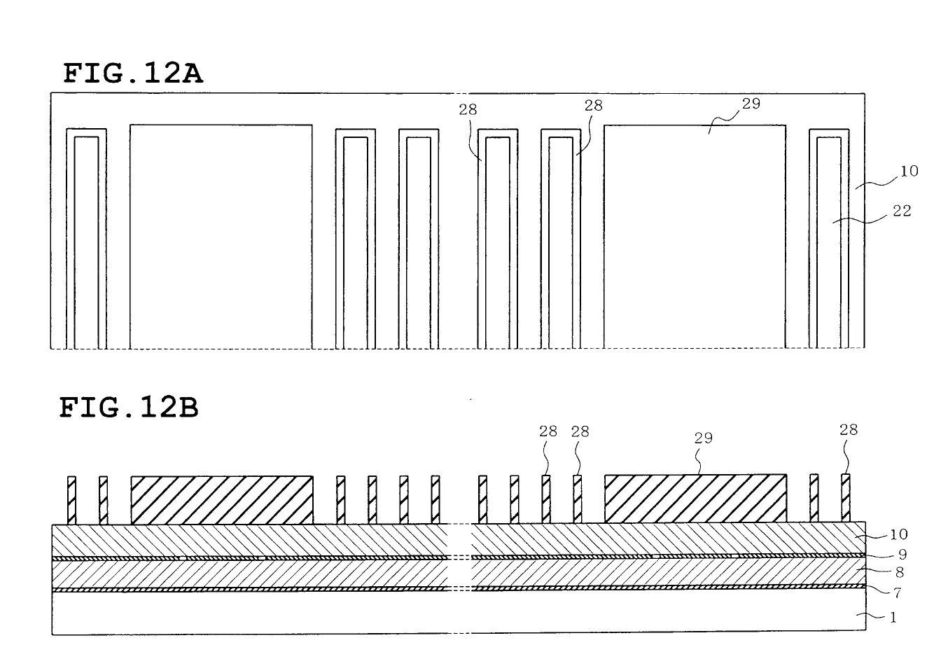

Thereafter, sidewall mask pattern 26, dummy mask pattern 23, and sidewall line pattern 25 are used as masks for patterning silicon nitride film 15 by RIE. As a result, dummy line pattern 28 also referred to as second sidewall line pattern is formed in word line forming region 17 as shown in FIGS. 12A and 12B. In select gate line forming region 19, on the other hand, dummy mask pattern 29 also referred to as fourth mask pattern is formed.

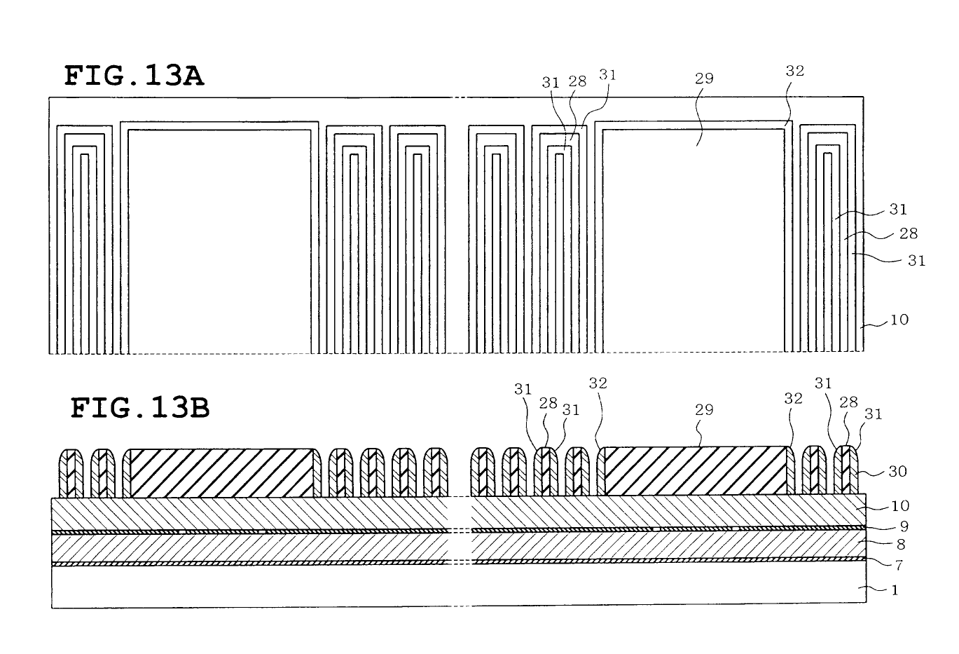

Then, silicon oxide film 30 also referred to as a fourth film is blanket deposited by CVD (chemical vapor deposition) in the thickness substantially equal to width d to cover dummy line pattern 28 and dummy mask pattern 29 by silicon oxide film 30. Then, silicon oxide film 30 is etched back by anisotropic etching such as RIE to expose the upper surface of dummy line pattern 28 and dummy mask pattern 29 as shown in FIGS. 13A and 13B. This leaves sidewall line pattern 31 also referred to as a second sidewall line pattern along the sidewall or the side surface of dummy line pattern 28, as well as sidewall mask pattern 32 also referred to as a second sidewall mask pattern along the sidewall or the side surface of dummy mask pattern 29. The widths of sidewall line pattern 31 and sidewall mask pattern 32 are controlled to width d.

Then, as shown in FIGS. 14A and 14B, dummy line pattern 28 and dummy mask pattern 29 are removed by wet etching using wet etchant such as phosphoric acid. As a result, shrink pattern A comprising sidewall line pattern 31 and sidewall mask pattern 32 are formed in word line forming region 17. The number of line patterns within shrink pattern A formed in word line forming region 17 amounts to “34” which is the sum of “32” sidewall line patterns 31 and “2” sidewall mask patterns 32. Thus, the first embodiment allows formation of line patterns amounting to a number which is not a multiple of “4”.

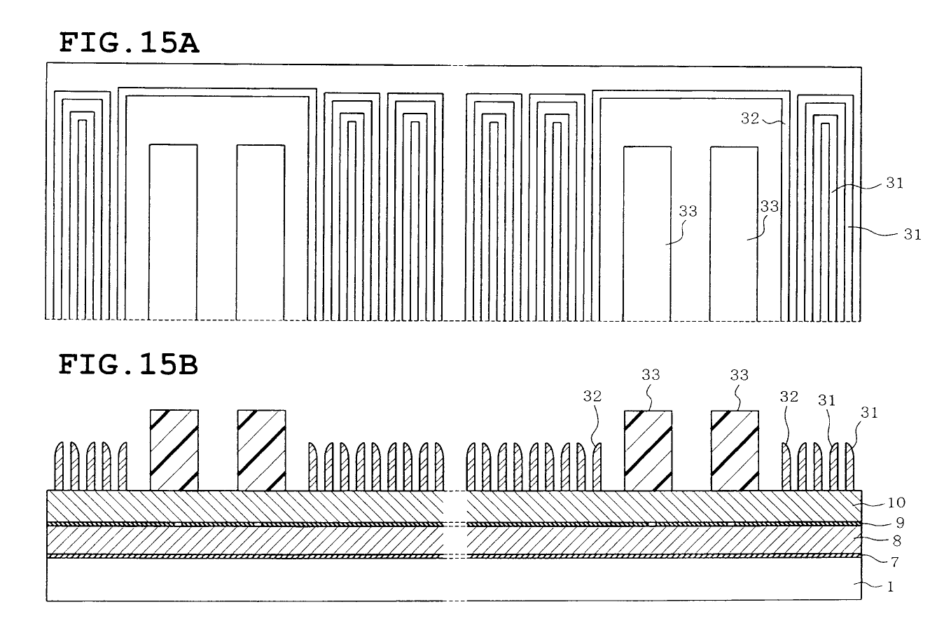

Then, as shown in FIGS. 15A and 15B, photoresist pattern 33 is formed in select gate line forming region 19 by normal photolithography above the base structure including polycrystalline silicon layer 10, interelectrode insulating film 9, and polycrystalline silicon layer 8 such that sidewall mask pattern 32 stays uncovered. At the same time, a photoresist not shown is formed above the base structure residing in the peripheral circuit region not shown. Photoresist patterns 33 formed in select gate line forming regions 19 are used for forming select gate line patterns and the photoresist patterns formed in the peripheral circuit regions are used for forming peripheral circuit patterns such as a gate patterns for peripheral circuit transistors.

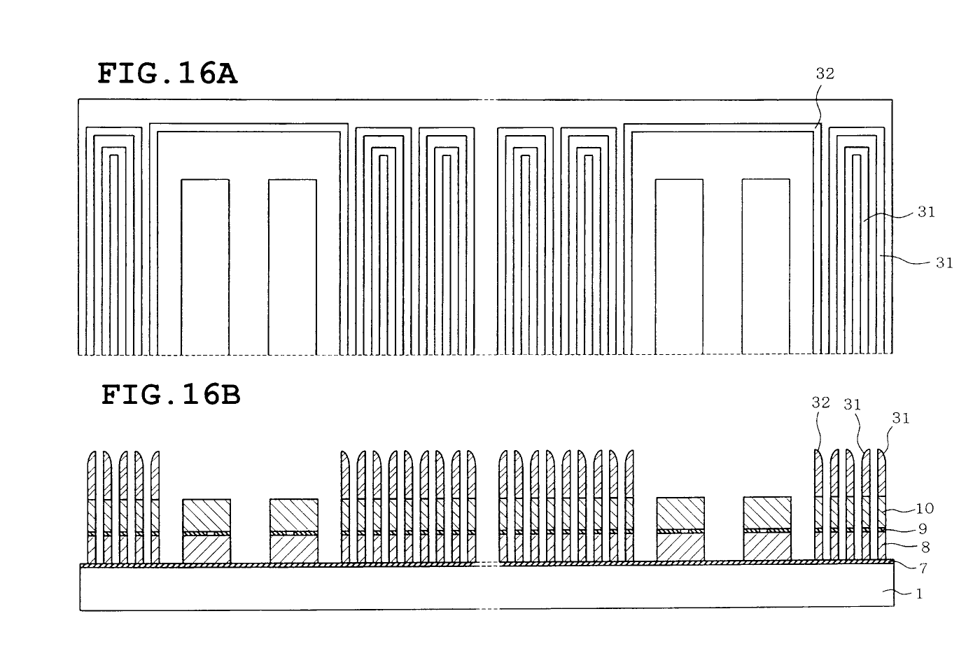

Then, as shown in FIGS. 16A and 16B, word line forming region 17 and select gate line forming region 19 are etched at the same time. That is, in word line forming region 17, sidewall line pattern 31 and sidewall mask pattern 32 are used as masks for etching polycrystalline silicon layer 10, interelectrode insulating film 9, and polycrystalline silicon layer 8. Similarly, in select gate line forming region 19, photoresist pattern 33 is used as a mask for etching polycrystalline silicon layer 10, interelectrode insulating film 9, and polycrystalline silicon layer 8.

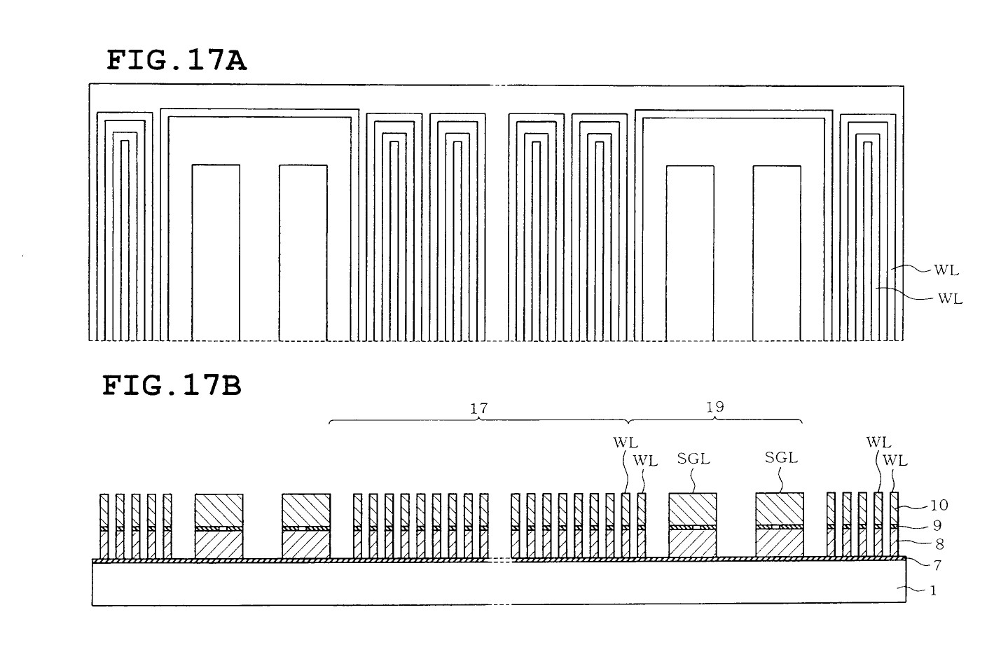

Thereafter, as shown in FIGS. 17A and 17B, the masks, namely sidewall line pattern 31, sidewall mask pattern 32, and photoresist pattern 33 are removed. As a result, word line forming region 17 is patterned into 34 memory cells and word lines WL which is a quadruple of the 8 lines present in the original photoresist pattern 19 plus 2 additional lines. In select gate line forming regions 19, patterns of select transistors and select gate lines SGL 1 and SGL 2 are typically formed, whereas in the peripheral circuit regions, the gate patterns of peripheral circuit transistors are typically formed.

Of note is that, in the process step shown in FIGS. 13A and 13B, sidewall line pattern 31 is formed along the entirety of the sidewall of dummy line pattern 28. This means that sidewall line pattern 31 is formed as a closed loop that surrounds dummy pattern 28. Use of such close looped sidewall line pattern 31 as a mask in etching the base structure results in closed loop memory cells and word lines WL. Closed loop word lines WL, for instance, are defective in that the interconnect lines are connected and thus, are not electrically isolated from the adjacent interconnect lines and thus, do not function properly. Thus, a step for removing the ends of the closed loops of the patterned base structure is carried out to allow the device to function properly.

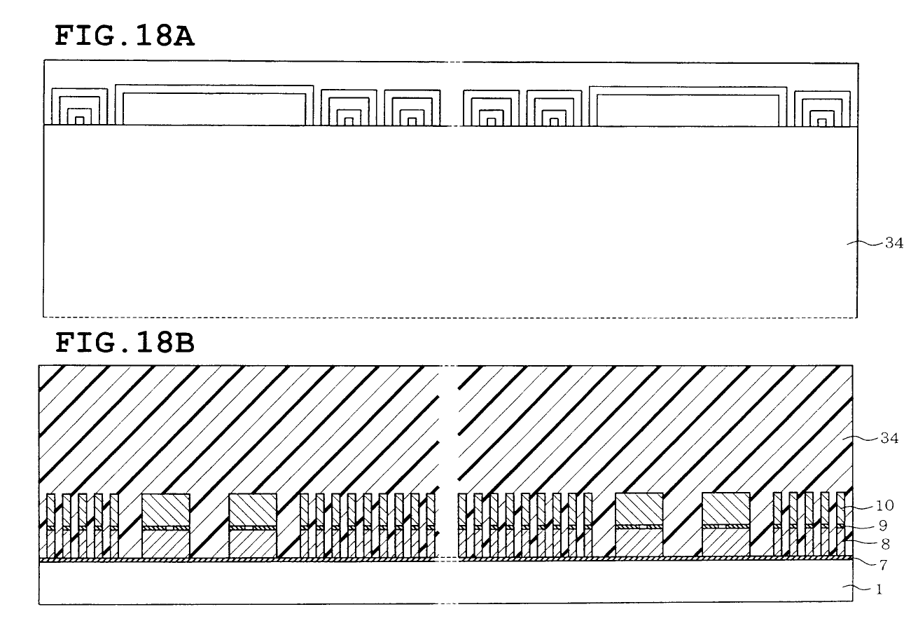

The process is elaborated with reference to FIGS. 18A and 18B in which photoresist pattern 34 are formed in word line forming region 17 and select gate line forming region 19 by an ordinary photolithography. Photoresist pattern 34 cover the patterned base structure exclusive of the closed loop ends.

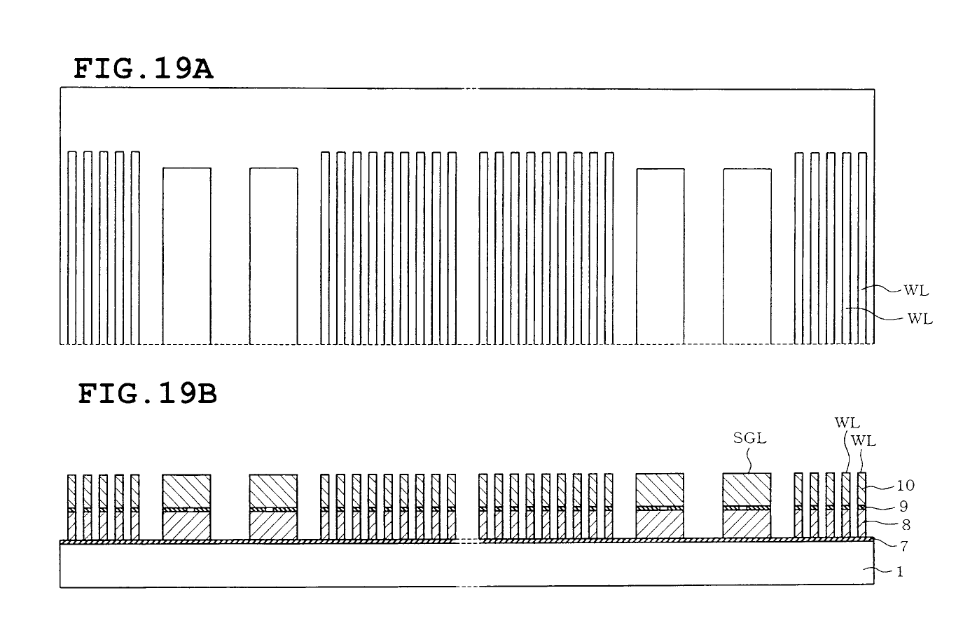

Then, using photoresist pattern 34 as masks, only the closed loop ends of the patterned base structure are etched away and photoresist pattern 34 is removed as shown in FIG. 19B. Thus, isolated line and space patterns are formed, which in this case, serve as memory cells and word lines WL.

The first embodiment described above allows formation of a pattern having a number of line patterns that is not a multiple of 4 through a process for reducing the pitch of the original exposure pattern 18 to ¼.

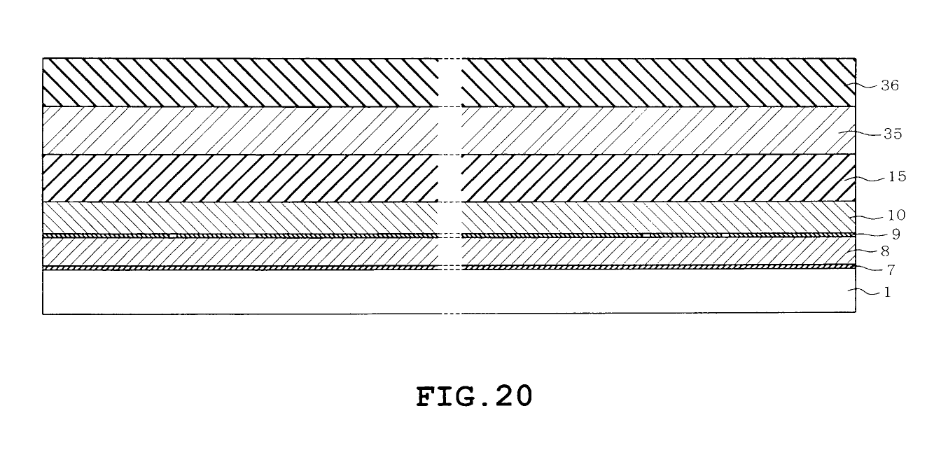

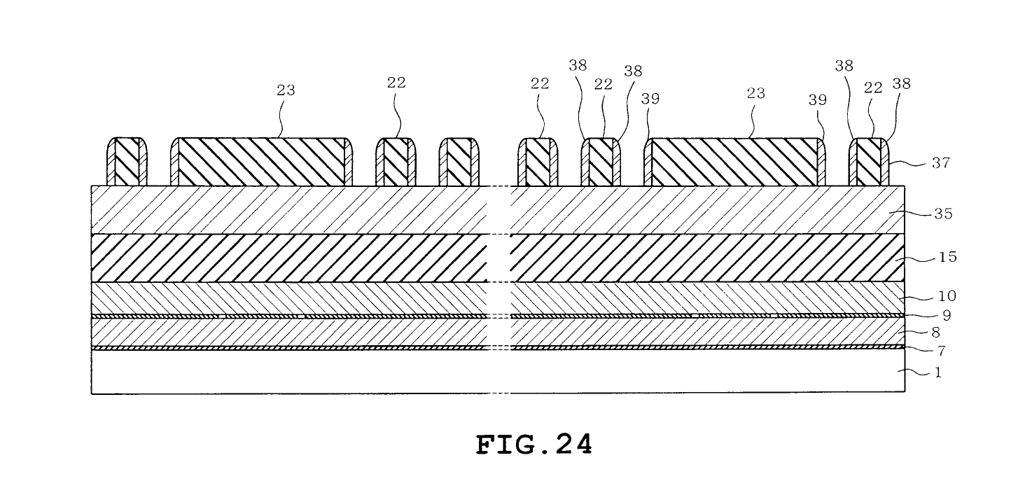

FIGS. 20 to 31 illustrate a second embodiment. Elements that are identical to the first embodiment are identified with identical reference symbols. The second embodiment differs from the first embodiment in that the base structure, i.e. polycrystalline silicon layer 10, interelectrode insulating film 9, and polycrystalline silicon layer 8 that were etched using photoresist 33, are etched with an additional hard mask. The second embodiment will be described in detail hereinafter with reference to FIG. 20 to FIG. 31.

As shown in FIG. 20, silicon nitride film 15 serving as a mask also referred to as a fifth film is formed above polycrystalline silicon layer 10, whereafter polycrystalline silicon film 35 serving as a mask also referred to as a sixth film is formed above silicon nitride film 15. Further above polycrystalline silicon layer 35, silicon oxide film 36 serving as a mask also referred to as a seventh film is formed.

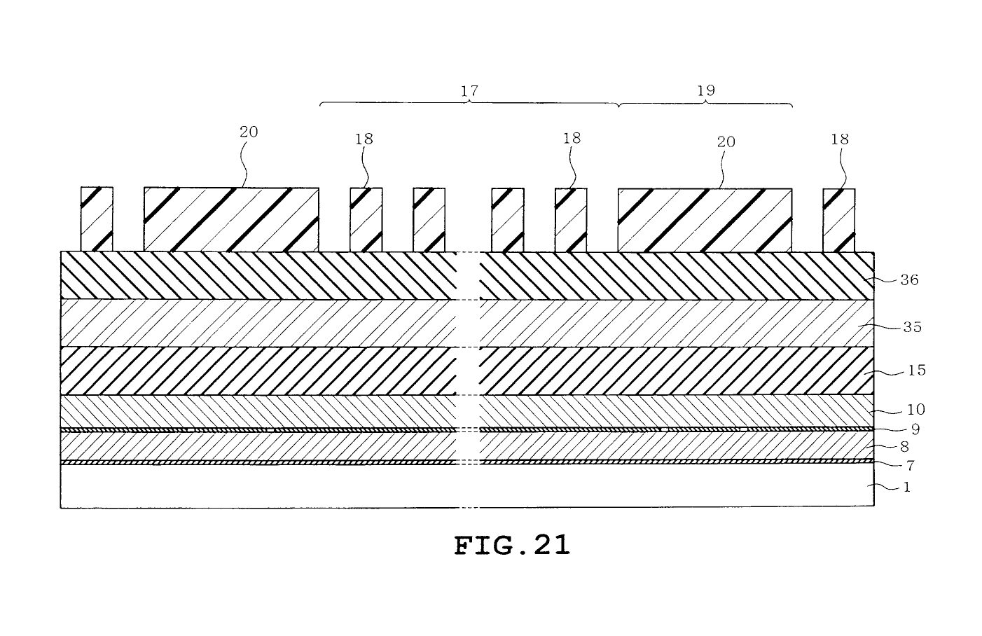

Referring to FIG. 21, as was the case in the first embodiment, photoresist pattern 18 is formed above silicon oxide film 36 by ordinary photolithography to form line and space patterns in word line forming region 17. The line patterns of photoresist pattern 18 are spaced from one another in the bit line direction which is oriented in the left and right direction as viewed in FIG. 6A and the line and space patterns are formed at first pitch P1. When photoresist pattern 18 is formed, photoresist pattern 20 is formed at the same time above silicon oxide film 16 by ordinary photolithograpy so as to extend along the entire length of select gate line forming region 19.

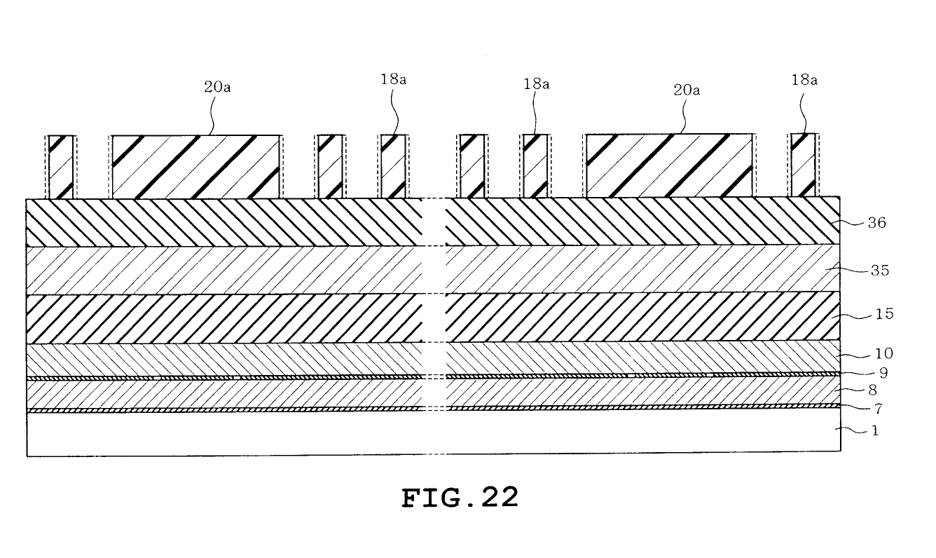

Then, as shown in FIG. 22, an ordinary slimming technique is used to slim photoresist patterns 18 and 20 to obtain photoresist patterns 18a and 20a.

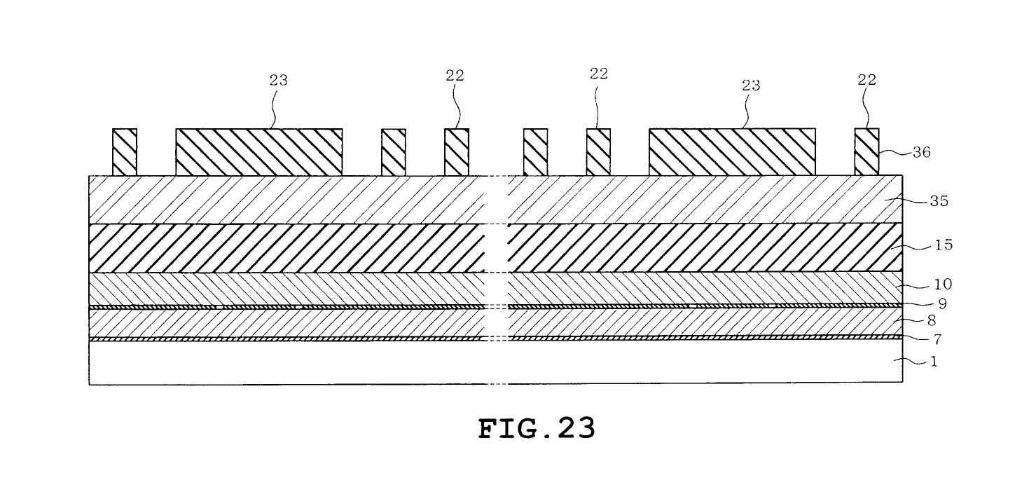

Then, as shown in FIG. 23, photoresist patterns 18a and 20a are used as masks to pattern silicon oxide film 36 by RIE. As a result, dummy line pattern 22 is formed in word line forming region 17. In select gate line forming region 19, on the other hand, dummy mask pattern 23 is formed.

Then, silicon nitride film 37 also referred to as an eighth film is blanket deposited by CVD (chemical vapor deposition) in the thickness substantially equal to width d to cover dummy line pattern 22 and dummy mask pattern 23 by silicon nitride film 37. Then, silicon nitride film 37 is etched back by anisotropic etching such as RIE to expose the upper surface of dummy line pattern 22 and dummy mask pattern 23. This leaves sidewall line pattern 38 also referred to as a first sidewall line pattern along the sidewall or the side surface of dummy line pattern 22, as well as sidewall mask pattern 39 also referred to as a first sidewall mask pattern along the sidewall or the side surface of dummy mask pattern 23. The widths of sidewall line pattern 38 and sidewall mask pattern 39 are controlled to width d.

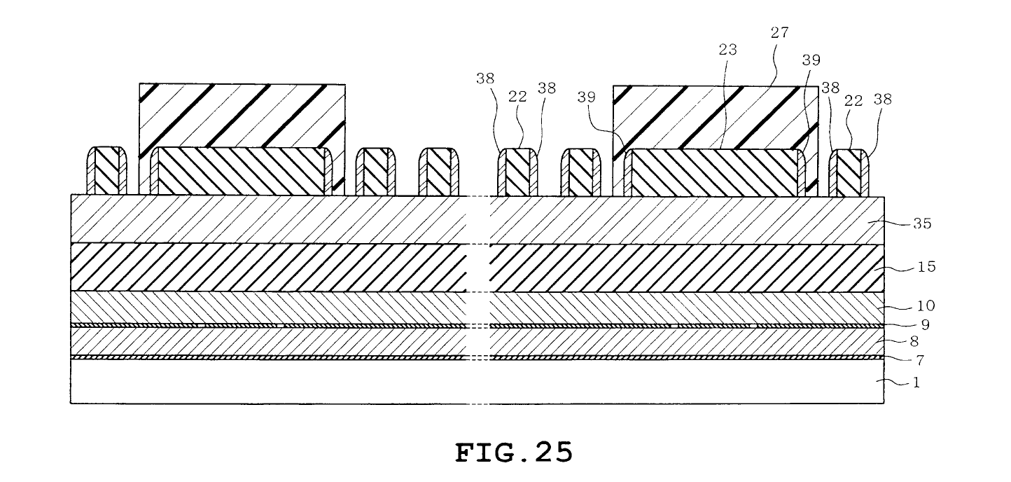

Then, as shown in FIG. 25, sidewall mask pattern 39 and dummy mask pattern 23 in select gate line forming region 19 are covered by photoresist pattern 27 using an ordinary photolithography as done in the first embodiment.

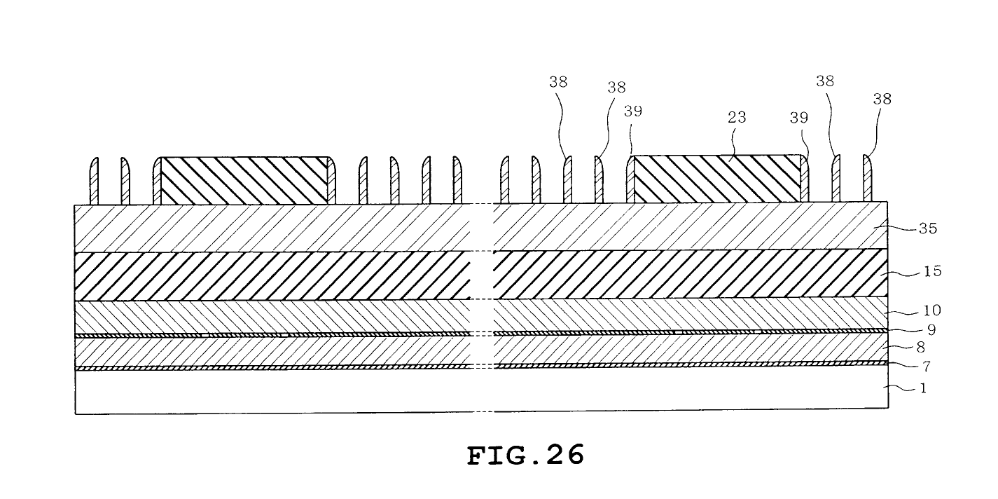

Then, as shown in FIG. 26, dummy line pattern 22 is removed by wet etching using wet etchant such as hydrofluoric acid. At this instance, dummy mask pattern 23 is covered by photoresist pattern 27 and thus, stays unremoved and is later used as a mask. FIG. 26 shows the structure with photoresist pattern 27 removed after the wet etching.

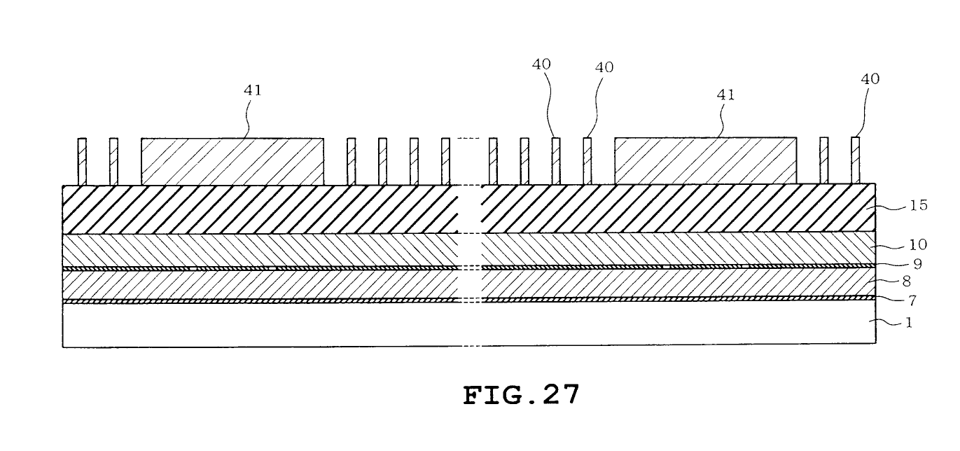

Thereafter, sidewall mask pattern 39, dummy mask pattern 23, and sidewall line pattern 38 are used as masks for patterning polycrystalline silicon film 35 by RIE. As a result, dummy line pattern 40 also referred to as second sidewall line pattern is formed in word line forming region 17 as shown in FIG. 27. In select gate line forming region 19, on the other hand, dummy mask pattern 41 also referred to as fourth mask pattern is formed.

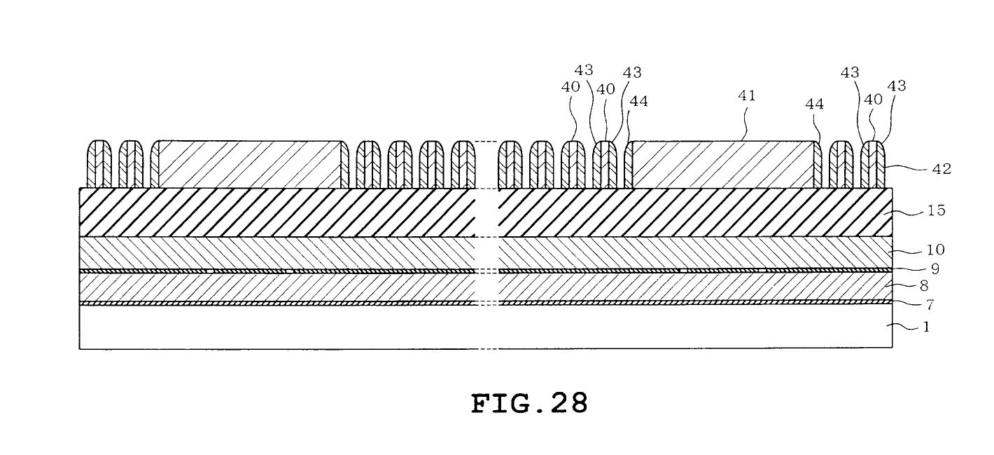

Then, silicon oxide film 42 also referred to as a ninth film is blanket deposited by CVD in the thickness substantially equal to width d to cover dummy line pattern 40 and dummy mask pattern 41 by silicon oxide film 42. Then, silicon oxide film 42 is etched back by anisotropic etching such as RIE to expose the upper surface of dummy line pattern 40 and dummy mask pattern 41. This leaves sidewall line pattern 43 also referred to as a third sidewall line pattern along the sidewall or the side surface of dummy line pattern 40, as well as sidewall mask pattern 44 also referred to as a second sidewall mask pattern along the sidewall or the side surface of dummy mask pattern 41 as shown in FIG. 28. The widths of sidewall line pattern 43 and sidewall mask pattern 44 are controlled to width d.

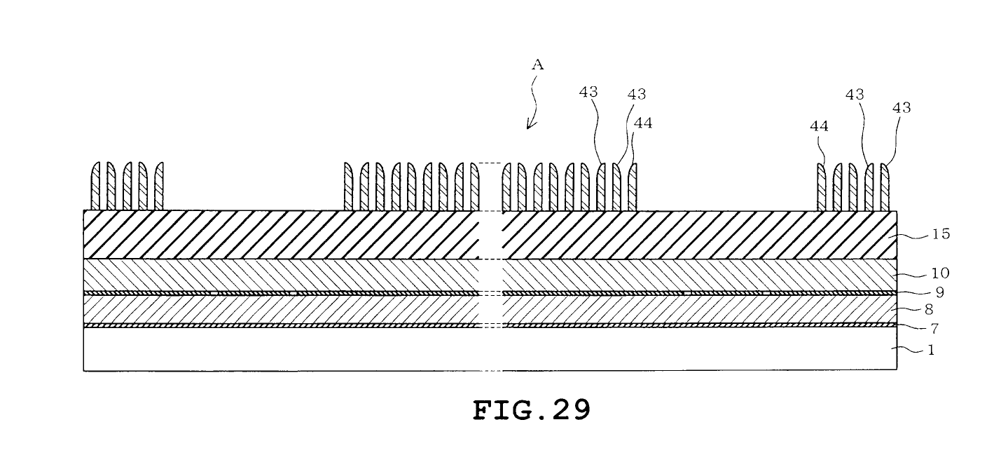

Then, as shown in FIG. 29, dummy line pattern 40 and dummy mask pattern 41 are removed by wet etching using wet etchant such as phosphoric acid. As a result, shrink pattern A comprising sidewall line pattern 43 and sidewall mask pattern 44 are formed in word line forming region 17. The number of line patterns within shrink pattern A formed in word line forming region 17 amounts to “34” which is the sum of “32” sidewall line patterns 43 and “2” sidewall mask patterns 44. Thus, the second embodiment allows formation of line patterns amounting to a number which is not a multiple of “4”.

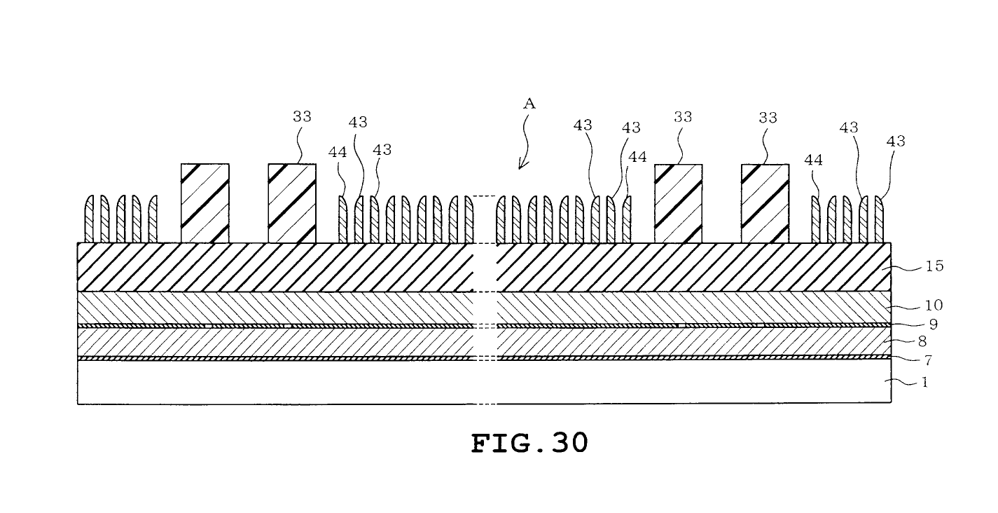

Then, as shown in FIG. 30, photoresist pattern 33 is formed in select gate line forming region 19 by normal photolithography above silicon nitride film 15 such that sidewall mask pattern 44 stays uncovered. At the same time, a photoresist not shown is formed above the base structure residing in the peripheral circuit not shown. Photoresist patterns 33 formed in select gate line forming regions 19 are used for forming select gate line patterns and the photoresist patterns formed in the peripheral circuit regions are used for forming peripheral circuit patterns such as gate patterns for peripheral circuit transistors.

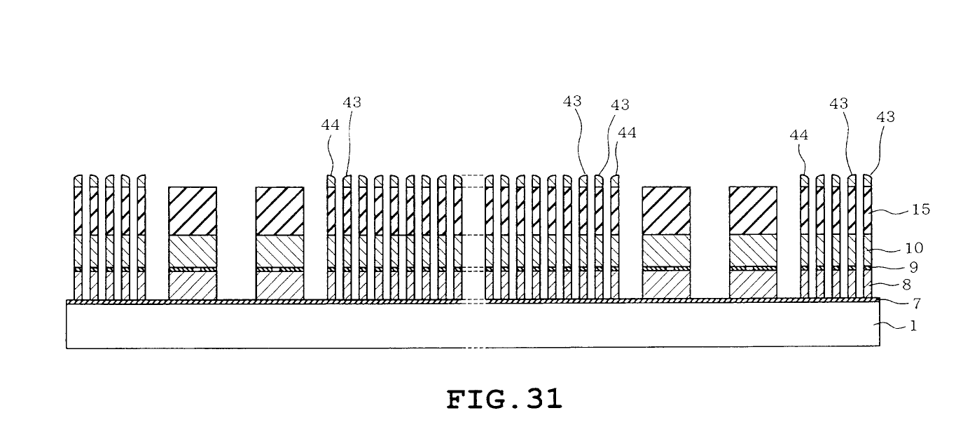

Then, as shown in FIG. 31, silicon nitride film 15 and the base structures in word line forming region 17 and select gate line forming region 19 are etched at the same time. That is, in word line forming region 17, sidewall line pattern 43 and sidewall mask pattern 44 are used as masks for patterning silicon nitride film 15 by etching, whereafter polycrystalline silicon layer 10, interelectrode insulating film 9, and polycrystalline silicon layer 8 are etched using sidewall line pattern 43, sidewall mask pattern 44, and the patterned silicon nitride film 15 as masks. Similarly, in select gate line forming region 19 and peripheral circuit region, photoresist pattern 33 and silicon nitride film 15 are used as masks for etching polycrystalline silicon layer 10, interelectrode insulating film 9, and polycrystalline silicon layer 8.

Thereafter, the masks, namely sidewall line pattern 43, sidewall mask pattern 44, silicon nitride film 15, and photoresist pattern 33 are removed. As a result, word line forming region 17 is patterned into 34 memory cells and word lines WL which is a quadruple of the 8 lines present in the original photoresist pattern 18 plus 2 additional lines as shown in FIGS. 17A and 17B. In select gate line forming regions 19, patterns of select transistors and select gate lines SGL 1 and SGL 2 are typically formed, whereas in the peripheral circuit regions, the gate patterns of peripheral circuit transistors are typically formed.

The rest of the process flow which is not described above remains the same as the first embodiment. Thus, the second embodiment also provides the operation and effect similar to those of the first embodiment. Especially because the second embodiment is configured to etch the base structure, in this case, polycrystalline silicon layer 10, interelectrode insulating film 9, and polycrystalline silicon layer 8 in select gate line forming region 19 and peripheral circuit region using photoresist pattern 33 and silicon nitride film 15 as a mask, the base structure can be etched without the risk of the mask being etched away.

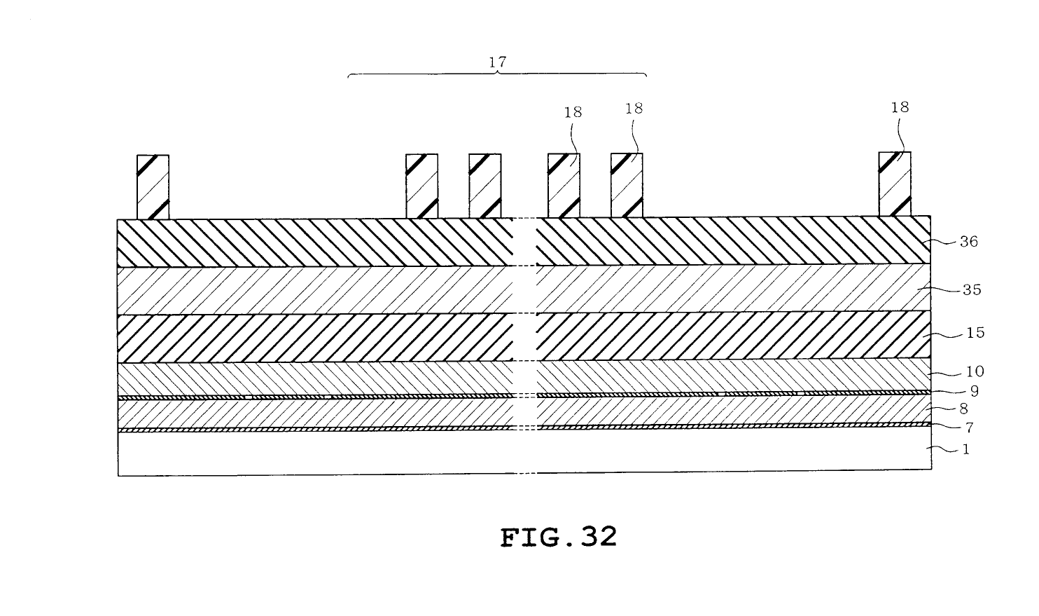

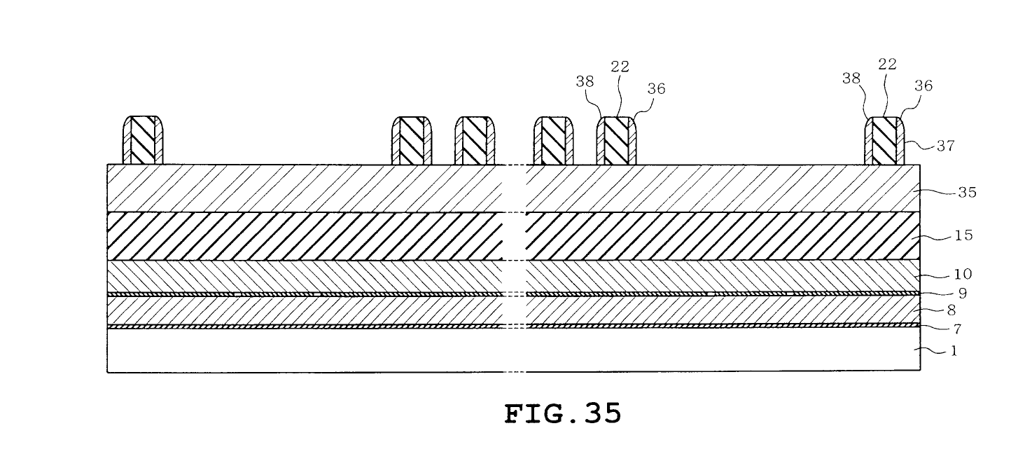

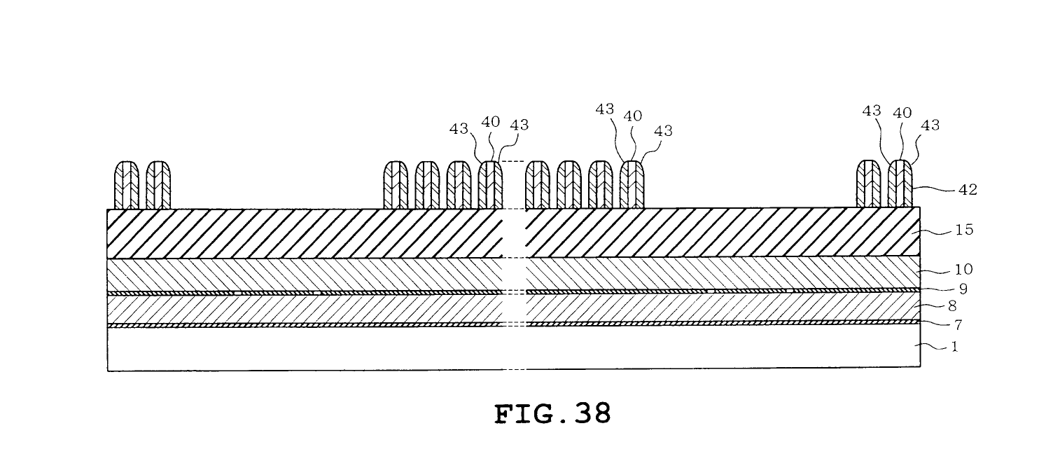

FIGS. 32 to 41 illustrate a third embodiment. Elements that are identical to the second embodiment are identified with identical reference symbols. Second embodiment was configured to form shrink pattern A having 34 (32+2=34) lines within word line forming region 17. In contrast, the third embodiment is configured to form shrink pattern A having 30 (32−2) lines within word line forming region 17. The third embodiment is described hereinafter with reference to FIGS. 32 to 41.

As was the case in the second embodiment, silicon nitride film 15 serving as a mask is formed above polycrystalline silicon layer 10, whereafter polycrystalline silicon film 35 serving as a mask is formed above silicon nitride film 15 as shown in FIG. 20. Further above polycrystalline silicon layer 35, silicon oxide film 36 serving as a mask is formed.

Referring to FIG. 32, photoresist pattern 18 is formed above silicon oxide film 36 by ordinary photolithography to form line and space patterns in word line forming regions 17. The line patterns of photoresist pattern 18 are spaced from one another in the bit line direction which is oriented in the left and right direction as viewed in FIG. 32 and the line and space patterns are formed at first pitch P1.

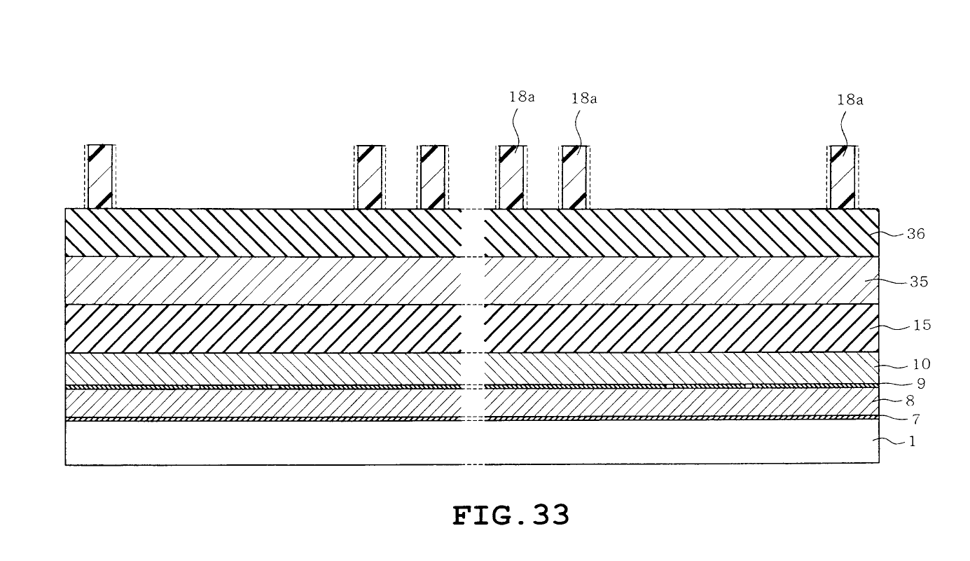

Then, as shown in FIG. 33, an ordinary slimming technique is used to slim photoresist pattern 18 to obtain photoresist pattern 18a as was the case in the second embodiment.

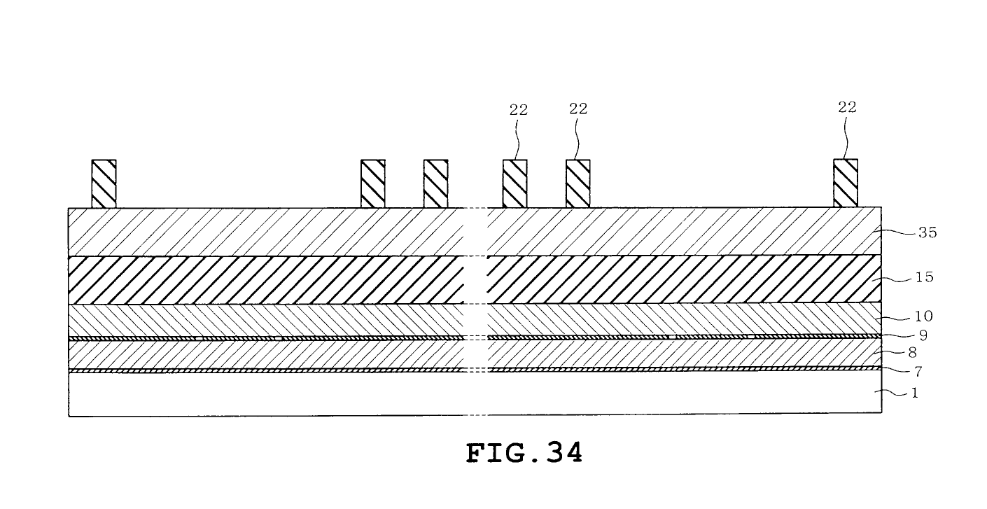

Then, as shown in FIG. 34, photoresist pattern 18a is used a mask to pattern silicon oxide film 36 by RIE. As a result, dummy line pattern 22 is formed in word line forming region 17.

Then, silicon nitride film 37 is blanket deposited by CVD in the thickness substantially equal to width d to cover dummy line pattern 22 by silicon nitride film 37. Then, silicon nitride film 27 is etched back by anisotropic etching such as RIE to expose the upper surface of dummy line pattern 22. This leaves sidewall line pattern 38 along the sidewall or the side surface of dummy line pattern 22.

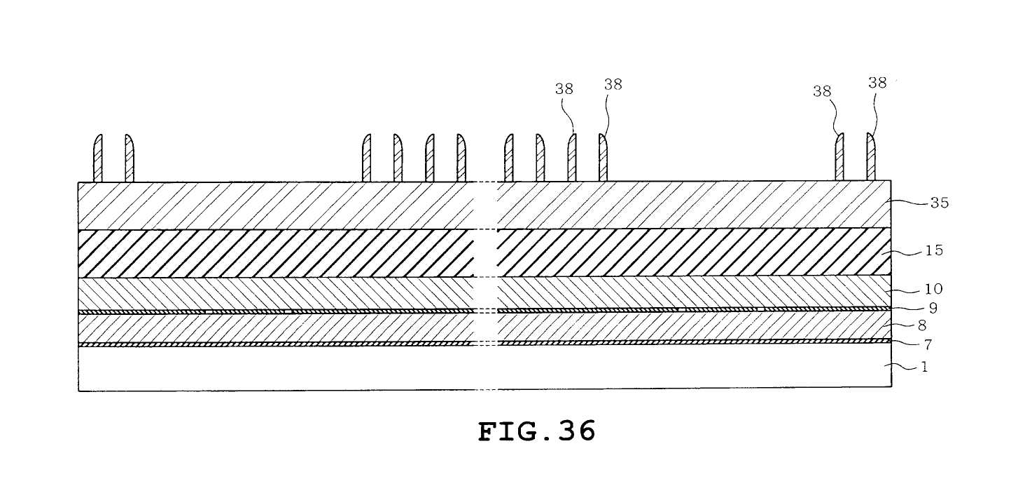

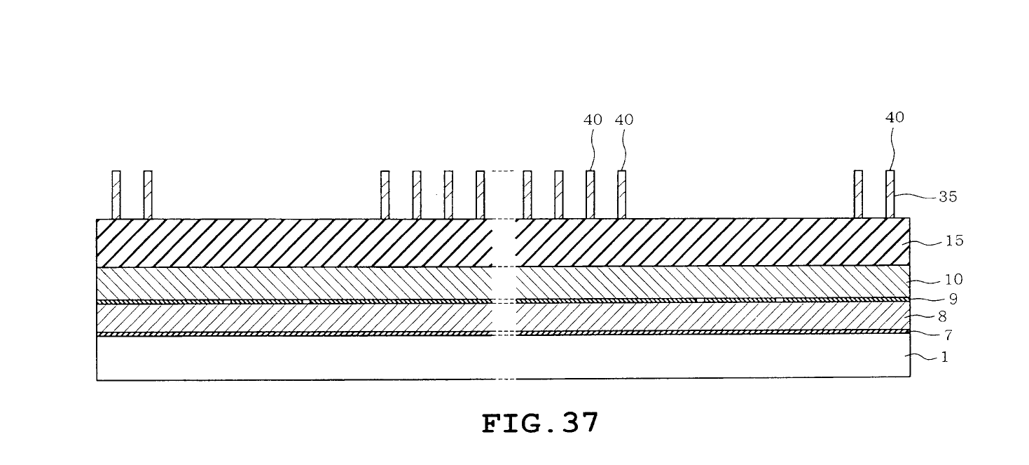

Then, as shown in FIG. 36, dummy line pattern 22 is removed by wet etching using wet etchant such as hydrofluoric acid. Thereafter, sidewall line pattern 38 is used as a mask for patterning polycrystalline silicon film 35 by RIE. As a result, dummy line pattern 40 is formed in word line forming region 17 as shown in FIG. 37.

Next, silicon oxide film 42 is blanket deposited by CVD in the thickness substantially equal to width d to cover dummy line pattern 40. Then, silicon oxide film 42 is etched back by anisotropic etching such as RIE to expose the upper surface of dummy line pattern 40. This leaves sidewall line pattern 43 along the sidewall or the side surface of dummy line pattern 40.

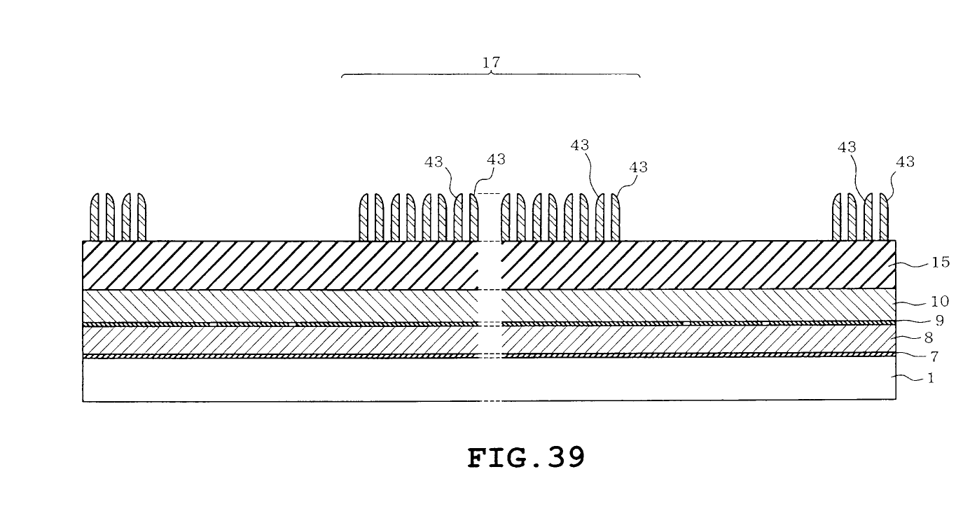

Thereafter, as shown in FIG. 39, dummy line pattern 40 is removed by wet etching using wet etchant such as phosphoric acid. As a result, shrink pattern A comprising line and space pattern defined by sidewall line pattern 43 is formed in word line forming region 17. The number of sidewall line patterns 43 formed in word line forming region 17 amounts to “32”.

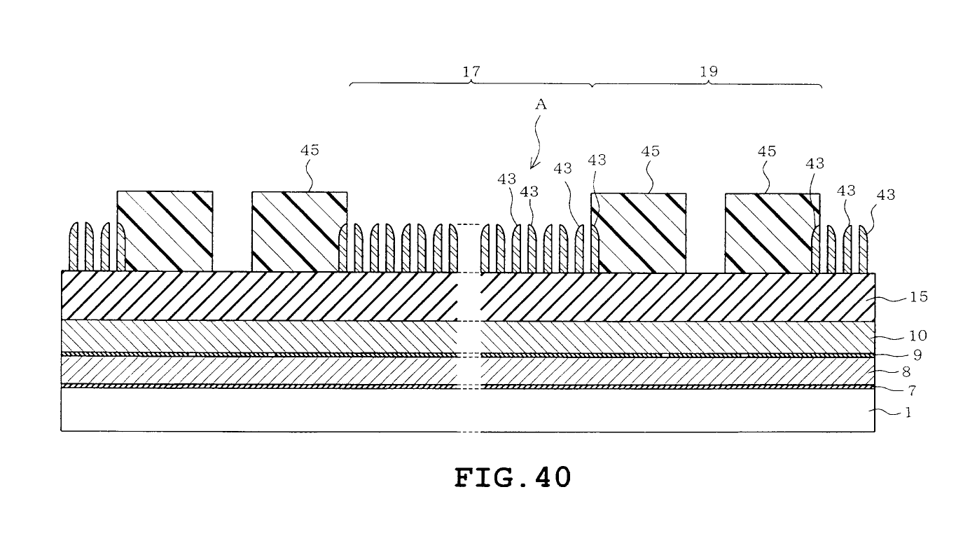

Then, as shown in FIG. 40, photoresist pattern 45 also referred to as a fifth mask pattern is formed in select gate line forming region 19 by normal photolithography such that photoresist pattern 45 covers the upper surface and the proximal sidewall of sidewall line pattern 43 residing in the word line forming region 17 which is in the closest proximity of select gate line forming region 19. The proximal sidewall in this case indicates the sidewall which is in the closest proximity of the adjacent select gate line forming region 19. Because sidewall line patterns 43 at the two ends of word line forming region 17 are covered by photoresist pattern 45, the number of sidewall line patterns 43 formed in word line forming region 17 is reduced to “30”. Thus, shrink pattern A comprising “30” sidewall line patterns 43 is formed within word line forming region 17.

At the same time, a photoresist pattern not shown is formed above the base structure residing in the peripheral circuit not shown. Photoresist patterns 45 formed in select gate line forming regions 19 is used for forming select gate line patterns and the photoresist patterns formed in the peripheral circuit regions are used for forming a peripheral circuit patterns such as gate patterns for peripheral circuit transistors.

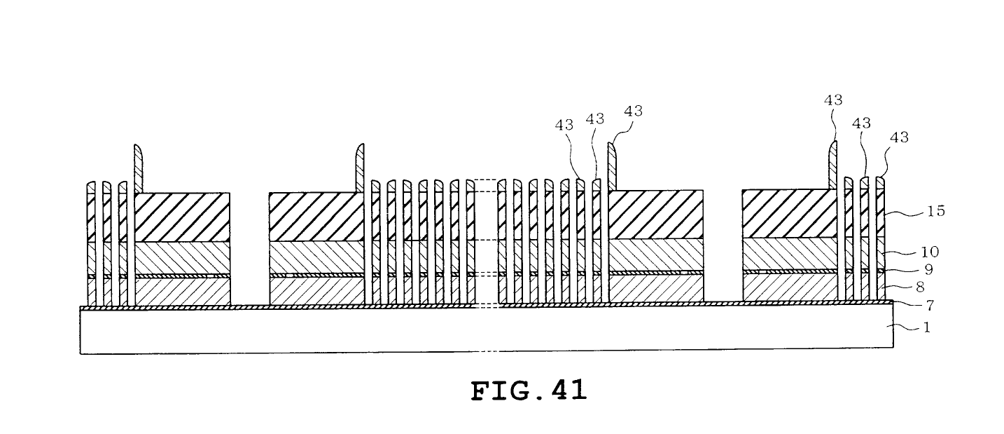

Then, as shown in FIG. 41, silicon nitride film 15 and the base structures in word line forming region 17 and select gate line forming region 19 are etched at the same time. That is, in word line forming region 17, sidewall line pattern 43 is used as a mask for patterning silicon nitride film 15 by etching, whereafter polycrystalline silicon layer 10, interelectrode insulating film 9, and polycrystalline silicon layer 8 are etched using sidewall line pattern 43 and the patterned silicon nitride film 15 as masks. Similarly, in select gate line forming region 19 and peripheral circuit region, photoresist pattern 45, sidewall line pattern 43, and silicon nitride film 15 are used as masks for etching polycrystalline silicon layer 10, interelectrode insulating film 9, and polycrystalline silicon layer 8.

Thereafter, the masks, namely sidewall line pattern 43, photoresist pattern 45, and silicon nitride film 15 are removed. As a result, word line forming region 17 is patterned into 30 memory cells and word lines WL which is a quadruple of the 8 lines present in the original photoresist pattern 19 minus 2 lines, that is, 32−2=30. In select gate line forming regions 19, patterns of select transistors and select gate lines SGL 1 and SGL 2 are typically formed, whereas in the peripheral circuit regions, the gate patterns of peripheral circuit transistors are typically formed.

The rest of the process flow which is not described above remains the same as the second embodiment. Thus, the third embodiment also provides the operation and effect similar to those of the second embodiment. Especially because the third embodiment is configured to form shrink pattern A having 30 (32−2=30) lines within word line forming region 17, number of lines which is not a multiple of 4, that is, a multiple of 4 minus 2 can be formed. In contrast, the first and the second embodiment allow formation of number of lines that is a multiple of 4 plus 2.

The above described embodiments may be modified or expanded as follows.

Alternative embodiments may be employed that forms number of lines that are multiples of 2 and not multiples of 4 other than 34 lines and 30 lines formed in the first and the second embodiments, respectively.

The foregoing embodiments were described primarily through isolation of gate electrodes MG serving as word lines WL of a NAND flash memory. Alternative embodiments may be applied to isolation of element isolation trenches 4 of a NAND flash memory. Further, alternative embodiments may be applied to manufacturing process flow of semiconductor devices other than a NAND flash memory.

Thus, the above described embodiments allow formation of a pattern having a number of line patterns that is not a multiple of 4 through a process for reducing the pitch of the original exposure pattern 18 to ¼.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
forming a first film and a second film in the listed sequence above a base structure;
forming a resist film above the second film;
patterning the resist film to form a first pattern in each of a plurality of first regions and to forma first mask pattern in a second region interposing adjacent first regions;
slimming a width of the first pattern and a width of the first mask pattern;
etching the second film using the first pattern and the first mask pattern as masks to form a second pattern and a second mask pattern;
forming a third film so as to cover the second pattern, the second mask pattern, and the first film;
etching back the third film to expose upper surfaces of the second pattern and the second mask pattern to form a first sidewall line pattern along a sidewall of the second pattern and to form a first sidewall mask pattern along a sidewall of the second mask pattern;
forming a third mask pattern comprising a resist film so as to cover the second mask pattern and the first sidewall mask pattern;
selectively removing the second pattern using the third mask pattern as a mask and thereafter removing the third mask pattern;
etching the first film using the first sidewall line pattern, the first sidewall mask pattern, and the second mask pattern as masks to form a second sidewall line pattern and a fourth mask pattern;
forming a fourth film so as to cover the second sidewall line pattern, the fourth mask pattern, and the base structure;
etching back the fourth film to expose upper surfaces of second sidewall line pattern and the fourth mask pattern to form a third sidewall line pattern along a sidewall of the second sidewall line pattern and to form a second sidewall mask pattern along a sidewall of the fourth mask pattern;
selectively removing the second sidewall line pattern and the fourth mask pattern; and
patterning the base structure using the third sidewall line pattern and the second sidewall mask pattern as masks.

2. The method according to claim 1, wherein the first film comprises a silicon nitride film and the second film comprises a silicon oxide film.

3. The method according to claim 1, wherein the third film comprises an amorphous silicon film and the fourth film comprises a silicon oxide film.

4. The method according to claim 1, wherein the base structure comprises a polycrystalline silicon layer, an interelectrode insulating film, and a polycrystalline silicon layer stacked in the listed sequence.

5. The method according to claim 4, wherein the first region comprises a word line forming region and the second region comprises a select gate line forming region.

6. The method according to claim 5, further comprising removing closed loop ends of the patterned base structure.

7. A method of manufacturing a semiconductor device comprising:
forming a fifth film, a sixth film, and a seventh film in the listed sequence above a base structure;
forming a resist film above the seventh film;
patterning the resist film to form a first pattern in each of a plurality of first regions and to forma first mask pattern in a second region interposing adjacent first regions;
slimming a width of the first pattern and a width of the first mask pattern;
etching the seventh film using the first pattern and the first mask pattern as masks to form a second pattern and a second mask pattern;
forming an eighth film so as to cover the second pattern, the second mask pattern and the sixth film;
etching back the eighth film to expose upper surfaces of the second pattern and the second mask pattern to form a first sidewall line pattern along a sidewall of the second pattern and to form a first sidewall mask pattern along a sidewall of the second mask pattern;
forming a third mask pattern comprising a resist film so as to cover the second mask pattern and the first sidewall mask pattern;
selectively removing the second pattern using the third mask pattern as a mask and thereafter removing the third mask pattern;
etching the sixth film using the first sidewall line pattern, the first sidewall mask pattern, and the second mask pattern as masks to form a second sidewall line pattern and a fourth mask pattern;
forming a ninth film so as to cover the second sidewall line pattern, the fourth mask pattern, and the fifth film;
etching back the ninth film to expose upper surfaces of the second sidewall line pattern and the fourth mask pattern to forma third sidewall line pattern along a sidewall of the second sidewall line pattern and to form a second sidewall mask pattern along a sidewall of the fourth mask pattern;
selectively removing the second sidewall line pattern and the fourth mask pattern; and
patterning the fifth film using the third sidewall line pattern and the second sidewall mask pattern as masks; and
patterning the base structure using the third sidewall line pattern, the second sidewall mask pattern, and the fifth film as masks.

8. The method according to claim 7, wherein the fifth film comprises a silicon nitride film, the sixth film comprises a polycrystalline silicon film, and the seventh film comprises a silicon oxide film.

9. The method according to claim 7, wherein the eighth film comprises a silicon nitride film and the ninth film comprises a silicon oxide film.

10. The method according to claim 7, wherein the base structure comprises a polycrystalline silicon layer, an interelectrode insulating film, and a polycrystalline silicon layer stacked in the listed sequence.

11. The method according to claim 10, wherein the first region comprises a word line forming region and the second region comprises a select gate line forming region.

12. The method according to claim 11, further comprising removing closed loop ends of the patterned base structure.

13. The method according to claim 7, wherein selectively removing the second sidewall line pattern and the fourth mask pattern is followed by forming a resist pattern for forming a select gate line above the fifth film located in the second region.

14. A method of manufacturing a semiconductor device comprising:
forming a fifth film, a sixth film, and a seventh film in the listed sequence above a base structure;
forming a resist film above the seventh film;
patterning the resist film to forma first pattern in each of a plurality of first regions;
slimming a width of the first pattern;
etching the seventh film using the first pattern as a mask to form a second pattern;
forming an eighth film so as to cover the second pattern and the sixth film;
etching back the eighth film to expose an upper surface of the second pattern to form a first sidewall line pattern along a sidewall of the second pattern;
selectively removing the second pattern;
etching the sixth film using the first sidewall line pattern as a mask to form a second sidewall line pattern;
forming a ninth film so as to cover the second sidewall line pattern and the fifth film;
etching back the ninth film to expose an upper surface of the second sidewall line pattern to form a third sidewall line pattern along a sidewall of the second sidewall line pattern;
selectively removing the second sidewall line pattern;
forming, in a second region interposing adjacent first regions, a fifth mask pattern covering an upper surface and a proximal sidewall of a proximal third sidewall line pattern, the proximal sidewall line pattern being located in the closest proximity of the second region among the plurality of third sidewall line patterns and the proximal sidewall being located in the closest proximity of the second region among sidewalls of the proximal third sidewall line pattern;
patterning the fifth film using the third sidewall line pattern and the fifth mask pattern as masks; and
patterning the base structure using the third sidewall line pattern, the fifth mask pattern, and the fifth film as masks.

15. The method according to claim 14, wherein the fifth film comprises a silicon nitride film, the sixth film comprises a polycrystalline silicon film, and the seventh film comprises a silicon oxide film.

16. The method according to claim 14, wherein the eighth film comprises a silicon nitride film and the ninth film comprises a silicon oxide film.

17. The method according to claim 14, wherein the base structure comprises a polycrystalline silicon layer, an interelectrode insulating film, and a polycrystalline silicon layer stacked in the listed sequence.

18. The method according to claim 17, wherein the first region comprises a word line forming region and the second region comprises a select gate line forming region.

19. The method according to claim 18, further comprising removing closed loop ends of the patterned base structure.

20. The method according to claim 14, wherein the base structure comprises a gate insulating film and a polycrystalline silicon layer stacked in the listed sequence above a silicon substrate.
